(19) United States
(12) Patent Application Publication
(10) Pub. No.: US 2025/0318264 A1
(43) Pub. Date: Oct. 9, 2025

(54) THIN FILM TRANSISTOR ARRAY, DISPLAY DEVICE INCLUDING THE SAME AND ELECTRONIC DEVICE

(71) Applicant: Samsung Display Co., LTD., Yongin-si (KR)

(72) Inventors: NAHYEON CHA, Yongin-si (KR); SUNKWUN SON, Yongin-si (KR); DONG HEE SHIN, Yongin-si (KR)

(21) Appl. No.: 19/017,316

(22) Filed: Jan. 10, 2025

(30) Foreign Application Priority Data
Apr. 9, 2024 (KR) 10-2024-0047831

(51) Int. Cl. H10D 86/40; H10D 86/60; H10H 29/32; H10H 29/49; H10K 59/121; H10K 59/131

(52) U.S. Cl. CPC H10D 86/441; H10D 86/60; H10H 29/32; H10H 29/49; H10K 59/1213; H10K 59/131

(57) ABSTRACT

A thin film transistor array includes a first gate line extending in a first direction, first and second data lines each extending in a second direction, a first write transistor connected to the first gate line and the first data line, a second write transistor connected to the first gate line and the second data line and arranged in the first direction from the first write transistor, a first driving transistor connected to the first write transistor and arranged in the second direction from the first write transistor, a second driving transistor connected to the second write transistor, arranged in the first direction from the first driving transistor, and arranged in the second direction from the second write transistor, and a first operation control transistor connected to the first driving transistor and the second driving transistor and arranged in the second direction from the first driving transistor.

### CROSS-REFERENCE TO RELATED APPLICATION

The present application claims priority to and the benefit of Korean Patent Application No. 10-2024-0047831, filed on Apr. 9, 2024, in the Korean Intellectual Property Office, the entire disclosure of which is incorporated herein by reference.

### BACKGROUND

### 1. Field

Aspects of some embodiments relate to a thin film transistor array, a display device including the same, and an electronic device including the display device.

### 2. Description of the Related Art

With the advancement of the information society, consumer demand for display devices for displaying images is increasing in various forms. Examples of display devices includes flat panel display devices such as liquid crystal display devices, field emission display devices, light emitting display devices, or the like.

Light emitting display devices may be organic light emitting display devices including organic light emitting diode elements operating as light emitting elements, inorganic light emitting display devices including inorganic semiconductor elements operating as light emitting elements, or light emitting diode LED display devices including subminiature light emitting diode elements (or micro light emitting diode elements) as light emitting elements.

The above information disclosed in this Background section is only for enhancement of understanding of the background and therefore the information discussed in this Background section does not necessarily constitute prior art.

### SUMMARY

Aspects of some embodiments include a thin film transistor array with a relatively improved degree of integration of pixel circuits.

Aspects of some embodiments include a display device including the thin film transistor array.

Aspects of some embodiments include an electronic device including the display device.

Additional aspects of some embodiments of the present disclosure will be set forth in the description which follows, and in part will be apparent from the description, or may be learned by practice of the inventive concepts.

A thin film transistor array according to some embodiments may include a first gate line extending in a first direction, a first data line extending in a second direction crossing the first direction, a second data line extending in the second direction and spaced apart from the first data line in the first direction, a first data write transistor electrically connected to the first gate line and the first data line, a second data write transistor electrically connected to the first gate line and the second data line and located in the first direction from the first data write transistor, a first driving transistor electrically connected to the first data write transistor and located in the second direction from the first data write transistor, a second driving transistor electrically connected to the second data write transistor, located in the first direction from the first driving transistor, and located in the second direction from the second data write transistor, and a first operation control transistor electrically connected to the first driving transistor and the second driving transistor and located in the second direction from the first driving transistor.

According to some embodiments, the first data write transistor, the first driving transistor, and the first operation control transistor may be arranged in a line along the second direction. According to some embodiments, the second data write transistor and the second driving transistor may be arranged in a line along the second direction.

According to some embodiments, the thin film transistor array may further include a first compensation transistor electrically connected to the first data write transistor and the first driving transistor and located in a direction opposite to the second direction from the first data write transistor, a first emission control transistor electrically connected to the first driving transistor and the first compensation transistor and located in the direction opposite to the second direction from the first compensation transistor, and a first initialization transistor electrically connected to the first emission control transistor and located in the direction opposite to the second direction from the first emission control transistor. According to some embodiments, the first initialization transistor, the first emission control transistor, the first compensation transistor, the first data write transistor, the first driving transistor, and the first operation control transistor may be arranged in a line along the second direction.

According to some embodiments, the thin film transistor array may further include a second compensation transistor electrically connected to the second data write transistor and the second driving transistor and located in the direction opposite to the second direction from the second data write transistor, a second emission control transistor electrically connected to the second driving transistor and the second compensation transistor and located in the direction opposite to the second direction from the second compensation transistor, and a second initialization transistor electrically connected to the second emission control transistor and located in the direction opposite to the second direction from the second emission control transistor. According to some embodiments, the second initialization transistor, the second emission control transistor, the second compensation transistor, the second data write transistor, and the second driving transistor may be arranged in a line along the second direction.

According to some embodiments, the second compensation transistor may be located in the first direction from the first compensation transistor. According to some embodiments, the second emission control transistor may be located in the first direction from the first emission control transistor. According to some embodiments, the second initialization transistor may be located in the first direction from the first initialization transistor.

According to some embodiments, the thin film transistor array may further include a first connection line electrically connecting a drain region of the first operation control transistor, a source region of the first driving transistor, and a source region of the second driving transistor to each other.

According to some embodiments, the first connection line may be arranged on the same layer as the first gate line.

According to some embodiments, the thin film transistor array may further include a second gate line extending in the first direction and spaced apart from the first gate line in the second direction, a third data write transistor electrically connected to the second gate line and the first data line and located in the second direction from the first operation control transistor, a fourth data write transistor electrically connected to the second gate line and the second data line and located in the first direction from the third data write transistor, a third driving transistor electrically connected to the third data write transistor and located in the second direction from the first operation control transistor, a fourth driving transistor electrically connected to the fourth data write transistor and located in the first direction from the third driving transistor, and a second operation control transistor electrically connected to the third driving transistor and the fourth driving transistor and located in the first direction from the first operation control transistor.

According to some embodiments, the second operation control transistor may be located between the second driving transistor and the fourth driving transistor.

According to some embodiments, the first data write transistor, the first driving transistor, the first operation control transistor, the third data write transistor, and the third driving transistor may be arranged in a line along the second direction. According to some embodiments, the second data write transistor, the second driving transistor, the second operation control transistor, the fourth data write transistor, and the fourth driving transistor may be arranged in a line along the second direction.

According to some embodiments, the third data write transistor may be located between the first operation control transistor and the third driving transistor. According to some embodiments, the fourth data write transistor may be located between the second operation control transistor and the fourth driving transistor.

According to some embodiments, the third driving transistor may be located between the first operation control transistor and the third data write transistor. According to some embodiments, the fourth driving transistor may be located between the second operation control transistor and the fourth data write transistor.

According to some embodiments, the thin film transistor array may further include a second connection line electrically connecting a drain region of the second operation control transistor, a source region of the third driving transistor, and a source region of the fourth driving transistor to each other.

According to some embodiments, the second connection line may be on the same layer as the first gate line and the second gate line.

According to some embodiments, the thin film transistor array may further include an emission control line extending in the first direction and configured to provide an emission control signal to a gate electrode of the first operation control transistor and a gate electrode of the second operation control transistor. According to some embodiments, the second connection line may cross the emission control line in a plan view.

According to some embodiments, the emission control line may include a first extension portion overlapping the gate electrode of the first operation control transistor in a plan view, a second extension portion on the same layer as the first extension portion, spaced apart from the first extension portion in the first direction, and overlapping the gate electrode of the second operation control transistor in a plan view, and a bridge electrode on a different layer from the first extension portion and the second extension portion and electrically connecting the first extension portion and the second extension portion to each other. According to some embodiments, the second connection line may cross the bridge electrode in a plan view.

A thin film transistor array according to some embodiments may include a first gate line extending in a first direction, a second gate line extending in the first direction and spaced apart from the first gate line in a second direction crossing the first direction, a first data line extending in the second direction, a second data line extending in the second direction and spaced apart from the first data line in the first direction, a first driving transistor electrically connected to the first gate line and the first data line, a second driving transistor electrically connected to the first gate line and the second data line and located in the first direction from the first driving transistor, a third driving transistor electrically connected to the second gate line and the first data line and located in the second direction from the first driving transistor, a fourth driving transistor electrically connected to the second gate line and the second data line, located in the first direction from the third driving transistor, and located in the second direction from the second driving transistor, a first operation control transistor electrically connected to the first driving transistor and the second driving transistor and located between the first driving transistor and the third driving transistor, and a second operation control transistor electrically connected to the third driving transistor and the fourth driving transistor and located between the second driving transistor and the fourth driving transistor.

According to some embodiments, the thin film transistor array may further include a first connection line electrically connecting a drain region of the first operation control transistor, a source region of the first driving transistor, and a source region of the second driving transistor to each other, and a second connection line electrically connecting a drain region of the second operation control transistor, a source region of the third driving transistor, and a source region of the fourth driving transistor to each other.

A display device according to some embodiments may include first to fourth light emitting elements adjacent to each other, a first driving transistor electrically connected to the first light emitting element, a second driving transistor electrically connected to the second light emitting element and located in a first direction from the first driving transistor, a third driving transistor electrically connected to the third light emitting element and located in a second direction crossing the first direction from the first driving transistor, a fourth driving transistor electrically connected to fourth light emitting element, located in the first direction from the third driving transistor, and located in the second direction from the second driving transistor, a first operation control transistor electrically connected to the first driving transistor and the second driving transistor and located between the first driving transistor and the third driving transistor, and a second operation control transistor electrically connected to the third driving transistor and the fourth driving transistor and located between the second driving transistor and the fourth driving transistor.

According to some embodiments, a first connection line electrically connecting a drain region of the first operation control transistor, a source region of the first driving transistor, and a source region of the second driving transistor to each other, and a second connection line electrically connecting a drain region of the second operation control transistor, a source region of the third driving transistor, and a source region of the fourth driving transistor to each other.

According to some embodiments, the thin film transistor array may include the plurality of pixel circuits. According to some embodiments, the thin film transistors included in each of the pixel circuits may be arranged in a line along one direction.

An electronic device according to some embodiments may include a display device and a power supply configured to provide power to the display device. The display device may include first to fourth light emitting elements adjacent to each other, a first driving transistor electrically connected to the first light emitting element, a second driving transistor electrically connected to the second light emitting element and located in a first direction from the first driving transistor, a third driving transistor electrically connected to the third light emitting element and located in a second direction crossing the first direction from the first driving transistor, a fourth driving transistor electrically connected to fourth light emitting element, located in the first direction from the third driving transistor, and located in the second direction from the second driving transistor, a first operation control transistor electrically connected to the first driving transistor and the second driving transistor and located between the first driving transistor and the third driving transistor, and a second operation control transistor electrically connected to the third driving transistor and the fourth driving transistor and located between the second driving transistor and the fourth driving transistor.

According to some embodiments, impurities may be relatively easily doped into a semiconductor substrate during manufacturing process of the thin film transistor array. In addition, adjacent pixel circuits may share at least one thin film transistor. Accordingly, a degree of integration of the pixel circuits in the thin film transistor array may be relatively improved. Therefore, a resolution and a display quality of the display device including the thin film transistor array may be relatively improved.

It is to be understood that both the foregoing general description and the following detailed description are explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to some embodiments.

FIG. 2 is a cross-sectional view of the display device of FIG. 1.

FIG. 3 is a plan view illustrating a thin film transistor array according to some embodiments.

FIG. 4 is a circuit diagram illustrating a first pixel circuit and a second pixel circuit included in the thin film transistor array of FIG. 3.

FIG. 5 is a circuit diagram illustrating a third pixel circuit and a fourth pixel circuit included in the thin film transistor array of FIG. 3.

FIG. 6 is a plan view schematically illustrating an example of the first to fourth pixel circuits included in the thin film transistor array of FIG. 3.

FIGS. 7 to 11 are layout views illustrating the first pixel circuit of FIG. 6.

FIG. 12 is a layout view illustrating the first to fourth pixel circuits of FIG. 6.

FIGS. 13 and 14 are enlarged views illustrating an area A of FIG. 6.

FIG. 15 is a plan view schematically illustrating an example of the first to fourth pixel circuits included in the thin film transistor array of FIG. 3.

FIG. 16 is an enlarged view illustrating an area B of FIG. 15.

FIG. 17 is a block diagram illustrating an electronic device according to some embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Illustrative, non-limiting embodiments will be more clearly understood from the following detailed description in conjunction with the accompanying drawings.

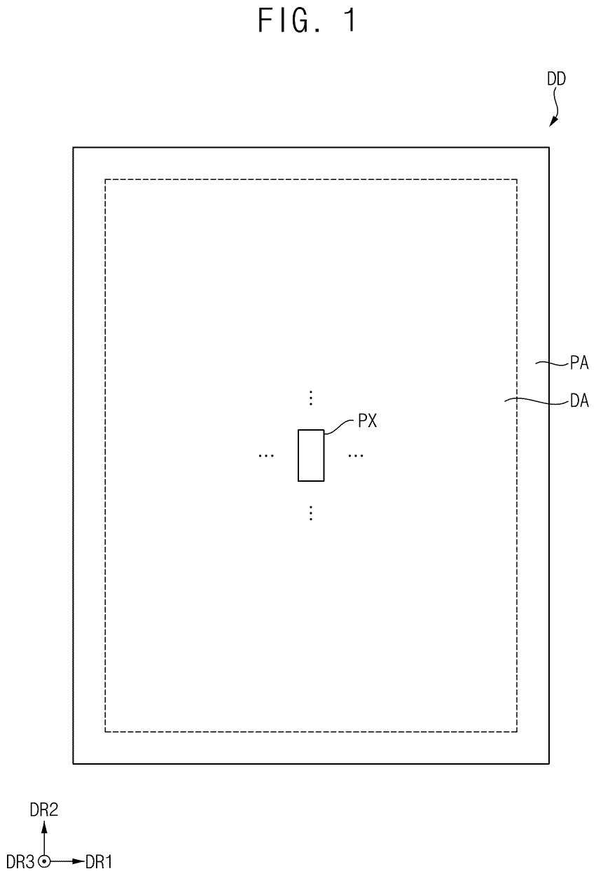

FIG. 1 is a plan view illustrating a display device according to some embodiments.

Referring to FIG. 1, according to some embodiments, a display device DD may have a display surface that displays an image. For example, the display surface may be parallel (or substantially parallel) to a plane defined by a first direction DR1 and a second direction DR2 crossing the first direction DR1, but embodiments are not limited thereto. The display device DD may display the image in a third direction DR3 through the display surface. For example, the second direction DR2 may be perpendicular to the first direction DR1. The third direction DR3 may be parallel (or substantially parallel) to a normal direction of the display surface. The display surface may correspond to an upper surface (or a front surface) of the display device DD.

The display device DD may include a display area DA and a peripheral area PA. The image may be displayed in the display area DA. A plurality of pixels PX for generating the image may be located in the display area DA. For example, each of the pixels PX may emit one of red light, green light, and blue light.

Each of the pixels PX may include a pixel circuit and a light emitting element. The pixel circuit may include at least one thin film transistor and at least one capacitor. The thin film transistor may generate a driving current and provide the generated driving current to the light emitting element. The light emitting element may emit light based on the driving current. For example, the light emitting element may include (or may be) an organic light emitting diode, an inorganic light emitting diode, a quantum dot light emitting diode, or the like. The image may be generated by combining light emitted from each of the pixels PX.

The peripheral area PA may be located around the display area DA. The peripheral area PA may be located outside the display area DA. For example, the peripheral area PA may surround the display area DA in a plan view. A driver (e.g., a data driver, a gate driver, or the like) may be located in the peripheral area PA. The driver may provide various driving signals for driving the pixels PX, such as a driving voltage, a gate signal, a data signal, or the like, to the display area DA.

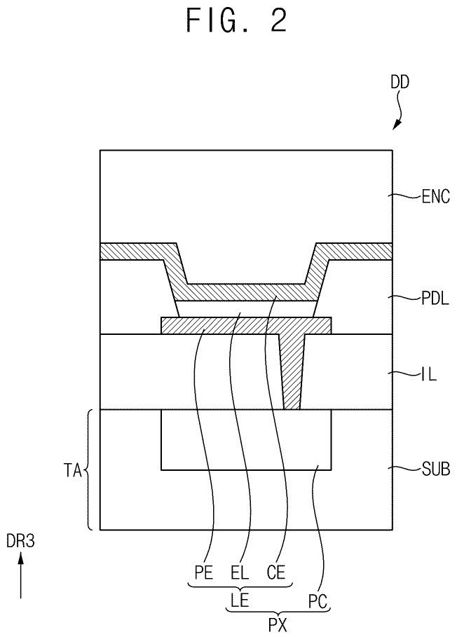

FIG. 2 is a cross-sectional view of the display device of FIG. 1.

Referring to FIGS. 1 and 2, according to some embodiments, the display device DD may include a thin film transistor array TA, the pixels PX, an insulating layer IL, a pixel defining layer PDL, and an encapsulation layer ENC. Each of the pixels PX may include the pixel circuit PC and the light emitting element LE electrically connected to the pixel circuit PC. The light emitting element LE may include a pixel electrode PE, an emission layer EL, and a common electrode CE.

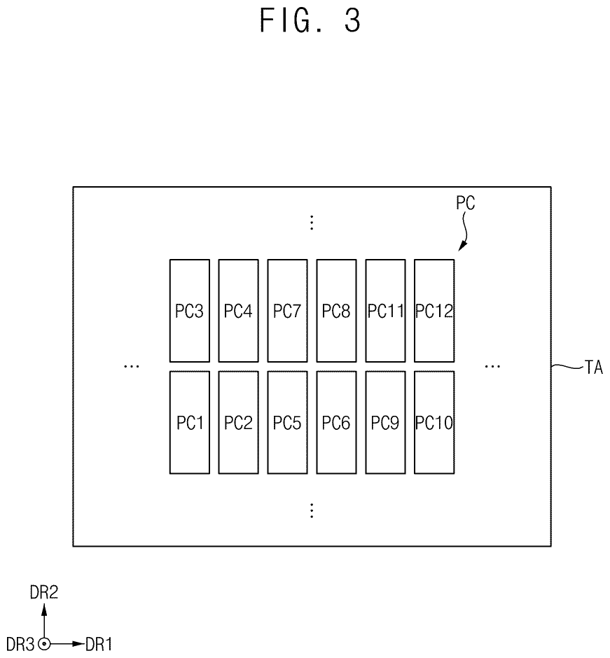

The thin film transistor array TA may include a substrate SUB and the pixel circuit PC located on the substrate SUB. Although only one pixel circuit PC is illustrated in FIG. 2, a plurality of pixel circuits PC may be located on the substrate SUB (refer to FIG. 3).

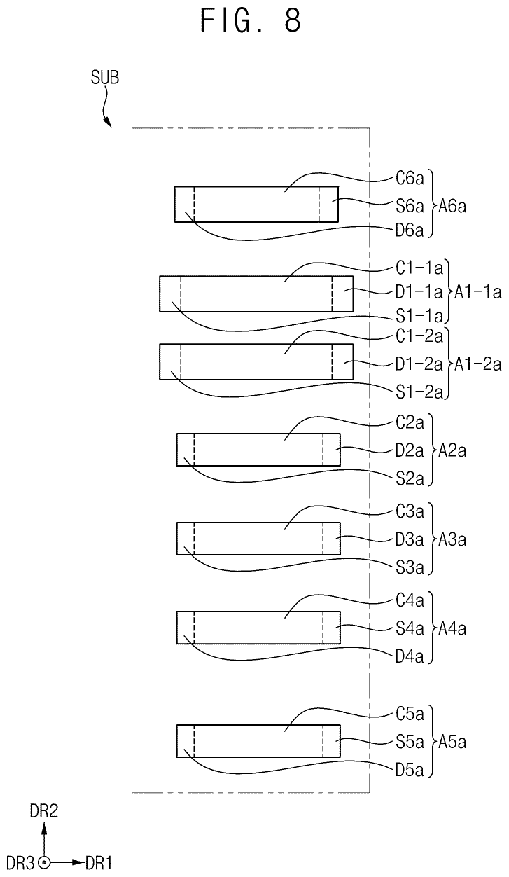

According to some embodiments, the substrate SUB may be a semiconductor substrate. For example, the substrate SUB may include silicon, germanium, or silicon/germanium, or may be a silicon-on-insulator (SOI) substrate. A plurality of active portions may be defined in the substrate SUB. This will be described in detail later with reference to FIG. 8.

The pixel circuits PC may be located on the substrate SUB. Each of the pixel circuits PC may include various driving elements (e.g., at least one thin film transistor, at least one capacitor, or the like), wires (e.g., a gate line, a data line, or the like) for driving a corresponding one of the light emitting elements LE.

The insulating layer IL may be located on the thin film transistor array TA. The insulating layer IL may include an organic insulating material and/or an inorganic insulating material.

The pixel electrode PE may be located on the insulating layer IL. For example, a plurality of pixel electrodes PE may be located on the insulating layer IL to correspond to the pixel circuits PC, respectively. Each of the pixel electrodes PE may be electrically connected to a corresponding one of the pixel circuits PC through a contact hole penetrating the insulating layer IL. For example, the pixel electrode PE may be an anode.

The pixel electrode PE may include a conductive material such as a metal, an alloy, a conductive metal nitride, a conductive metal oxide, a transparent conductive material, or the like. The pixel electrode PE may have a single-layered structure or a multi-layered structure including a plurality of conductive layers.

The pixel defining layer PDL may be located on the pixel electrode PE. The pixel defining layer PDL may cover a peripheral portion of the pixel electrode PE and may define a pixel opening exposing a central portion of the pixel electrode PE. The pixel defining layer PDL may include an organic insulating material.

The emission layer EL may be located on the pixel electrode PE. According to some embodiments, the emission layer EL may be located within the pixel opening to correspond to the corresponding pixel electrode PE. According to some embodiments, the emission layer EL may be located entirely on the display area DA. In some embodiments, the emission layer EL may include at least one of an organic emission material or quantum dot.

According to some embodiments, the organic emission material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

According to some embodiments, the quantum dot may include a core including a Group II-VI compound, a Group III-V compound, a Group IV-VI compound, a Group IV element, and/or a Group IV compound. According to some embodiments, the quantum dot may have a core-shell structure including the core and a shell surrounding the core. The shell may serve as a protection layer for preventing or reducing chemical denaturing of the core to maintain semiconductor characteristics, and may serve as a charging layer for imparting electrophoretic characteristics to the quantum dot.

The common electrode CE may be located on the emission layer EL. The common electrode CE may also be located on the pixel defining layer PDL. The common electrode CE may include a conductive material. For example, the common electrode CE may be a cathode.

The pixel electrode PE, the emission layer EL, and the common electrode CE may form the light emitting element LE. The light emitting element LE may further include various functional layers (e.g., a hole injection layer, a hole transport layer, an electron transport layer, an electron injection layer, or the like) located between the pixel electrode PE and the emission layer EL and/or between the emission layer EL and the common electrode CE.

The encapsulation layer ENC may be located on the common electrode CE. The encapsulation layer ENC may include at least one inorganic encapsulation layer and at least one organic encapsulation layer. According to some embodiments, the encapsulation layer ENC may include a first inorganic encapsulation layer located on the common electrode CE, an organic encapsulation layer located on the first inorganic encapsulation layer, and a second inorganic encapsulation layer located on the organic encapsulation layer. The encapsulation layer ENC may cover the light emitting elements LE on the entire display area DA. The encapsulation layer ENC may prevent or reduce instances of contaminants or impurities, moisture, or the like from penetrating into the light emitting elements LE from the outside.

The display device DD may further include various functional layers (e.g., a touch sensitive layer, a color filter layer, a light collecting layer, or the like) located on the encapsulation layer ENC.

FIG. 3 is a plan view illustrating a thin film transistor array according to some embodiments.

Referring to FIG. 3, the thin film transistor array TA may include the plurality of pixel circuits PC. According to some embodiments, the pixel circuits PC may be located in a matrix form along the first direction DR1 and the second direction DR2.

According to some embodiments, the thin film transistor array TA may include first to twelfth pixel circuits PC1, PC2, PC3, PC4, PC5, PC6, PC7, PC8, PC9, PC10, PC11, and PC12 electrically connected to first to twelfth light emitting elements, respectively.

The first pixel circuit PC1, the second pixel circuit PC2, the fifth pixel circuit PC5, the sixth pixel circuit PC6, the ninth pixel circuit PC9, and the tenth pixel circuit PC10 may be sequentially arranged along the first direction DR1. The third pixel circuit PC3, the fourth pixel circuit PC4, the seventh pixel circuit PC7, the eighth pixel circuit PC8, the eleventh pixel circuit PC11, and the twelfth pixel circuit PC12 may be sequentially arranged along the first direction DR1. The third pixel circuit PC3, the fourth pixel circuit PC4, the seventh pixel circuit PC7, the eighth pixel circuit PC8, the eleventh pixel circuit PC11, and the twelfth pixel circuit PC12 may be located in the second direction DR2 from the first pixel circuit PC1, the second pixel circuit PC2, the fifth pixel circuit PC5, the sixth pixel circuit PC6, the ninth pixel circuit PC9, and the tenth pixel circuit PC10, respectively.

According to some embodiments, at least some of the first to twelfth light emitting elements may emit light of different colors.

For example, the first light emitting element connected to the first pixel circuit PC1, the third light emitting element connected to the third pixel circuit PC3, the sixth light emitting element connected to the sixth pixel circuit PC6, and the eighth light emitting element connected to the eighth pixel circuit PC8 may each emit red light.

The second light emitting element connected to the second pixel circuit PC2, the fourth light emitting element connected to the fourth pixel circuit PC4, the ninth light emitting element connected to the ninth pixel circuit PC9, and the eleventh light emitting element connected to the eleventh pixel circuit PC11 may each emit green light.

The fifth light emitting element connected to the fifth pixel circuit PC5, the seventh light emitting element connected to the seventh pixel circuit PC7, the tenth light emitting element connected to the tenth pixel circuit PC10, and the twelfth light emitting element connected to the twelfth pixel circuit PC12 may each emit blue light.

According to some embodiments, the first to twelfth light emitting elements may all emit light of the same color.

For example, all of the first to twelfth light emitting elements may emit blue light. Red color conversion layer that converts blue light to red light may be located on the first light emitting element, the third light emitting element, the sixth light emitting element, and the eighth light emitting element, respectively. Green color conversion layers that converts blue light to green light may be located on the second light emitting element, the fourth light emitting element, the ninth light emitting element, and the eleventh light emitting element, respectively.

For another example, all of the first to twelfth light emitting elements may emit white light. Red color filters that selectively transmits red light may be located on the first light emitting element, the third light emitting element, the sixth light emitting element, and the eighth light emitting element, respectively. Green color filters that selectively transmits green light may be located on the second light emitting element, the fourth light emitting element, the ninth light emitting element, and the eleventh light emitting element, respectively. Blue color filters that selectively transmits blue light may be located on the fifth light emitting element, the seventh light emitting element, the tenth light emitting element, and the twelfth light emitting element, respectively.

The first pixel circuit PC1 and the second pixel circuit PC2 adjacent to each other in the first direction DR1 may share at least one thin film transistor. The third pixel circuit PC3 and the fourth pixel circuit PC4 adjacent to each other in the first direction DR1 may share at least one thin film transistor. The fifth pixel circuit PC5 and the sixth pixel circuit PC6 adjacent to each other in the first direction DR1 may share at least one thin film transistor. The seventh pixel circuit PC7 and the eighth pixel circuit PC8 adjacent to each other in the first direction DR1 may share at least one thin film transistor. The ninth pixel circuit PC9 and the tenth pixel circuit PC10 adjacent to each other in the first direction DR1 may share at least one thin film transistor. The eleventh pixel circuit PC11 and the twelfth pixel circuit PC12 adjacent to each other in the first direction DR1 may share at least one thin film transistor.

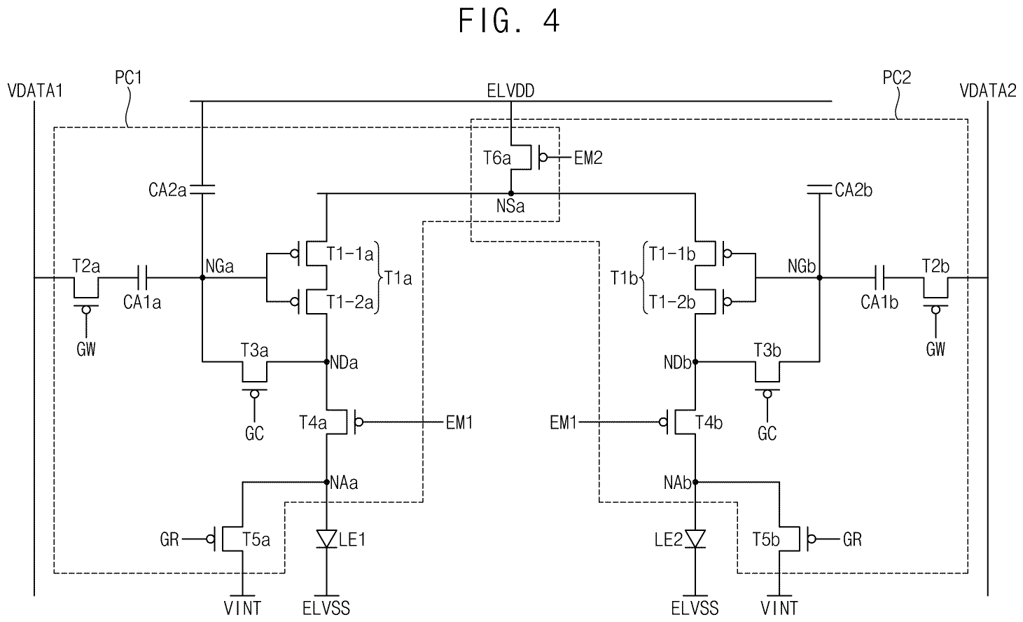

Hereinafter, the first to fourth pixel circuits PC1, PC2, PC3, and PC4 adjacent to each other in the first direction DR1 and the second direction DR2 will be described in more detail with reference to FIGS. 4 to 17. Description of the first to fourth pixel circuits PC1, PC2, PC3, and PC4 described below may be equally (or substantially equally) or similarly applied to the fifth to eighth pixel circuits PC5, PC6, PC7, and PC8 and the ninth to twelfth pixel circuits PC9, PC10, PC11, and PC12.

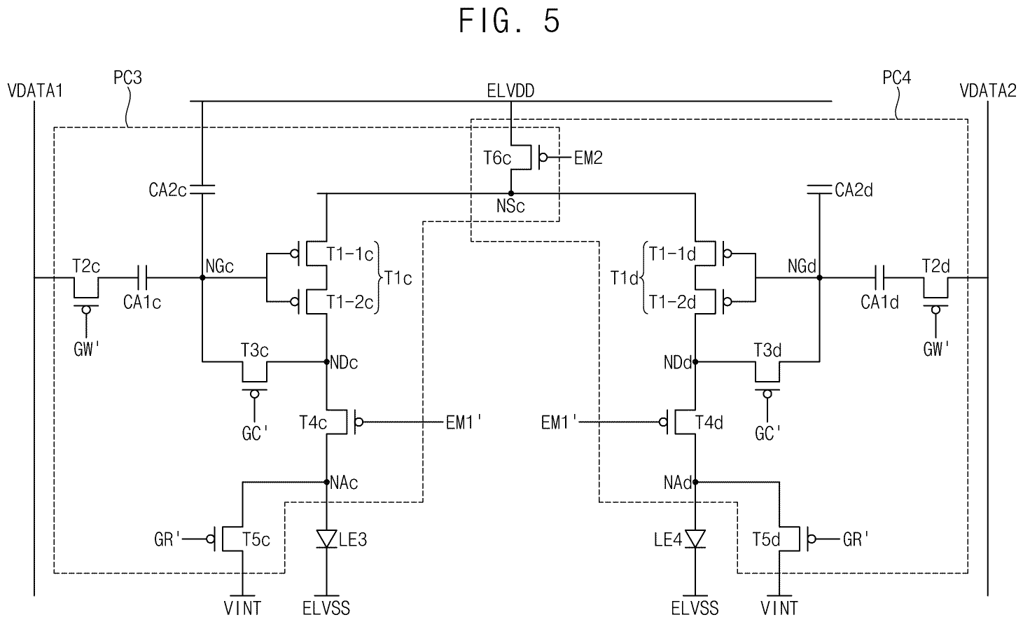

FIG. 4 is a circuit diagram illustrating a first pixel circuit and a second pixel circuit included in the thin film transistor array of FIG. 3. FIG. 5 is a circuit diagram illustrating a third pixel circuit and a fourth pixel circuit included in the thin film transistor array of FIG. 3.

The first to fourth pixel circuits PC1, PC2, PC3, and PC4 may have the same (or substantially the same) or similar structures. Therefore, the following description focuses on the first pixel circuit PC1, and some repeated descriptions may be omitted or simplified.

Referring to FIG. 4, according to some embodiments, the first pixel circuit PC1 connected to the first light emitting element LE1 may include a first driving transistor T1a, a first data write transistor T2a, a first compensation transistor T3a, a first emission control transistor T4a, a first initialization transistor T5a, a first operation control transistor T6a, a first-first capacitor CA1a, and a first-second capacitor CA2a.

The first driving transistor T1a may include a gate electrode connected to a first gate node NGa, a first electrode connected to a first source node NSa, and a second electrode connected to a first drain node NDa.

According to some embodiments, the first driving transistor T1a may be a dual transistor including a first-first driving transistor T1-1a and a first-second driving transistor T1-2a. The first-first driving transistor T1-1a may include a gate electrode connected to the first gate node NGa, a first electrode connected to the first source node NSa, and a second electrode connected to a first electrode of the first-second driving transistor T1-2a. The first-second driving transistor T1-2a may include a gate electrode connected to the first gate node NGa, the first electrode connected to the second electrode of the first-first driving transistor T1-1a, and a second electrode connected to the first drain node NDa.

The first data write transistor T2a may include a gate electrode configured to receive a data write gate signal GW, a first electrode configured to receive a first data voltage VDATA1, and a second electrode connected to a first electrode of the first-first capacitor CA1a.

The first compensation transistor T3a may include a gate electrode configured to receive a compensation gate signal GC, a first electrode connected to the first gate node NGa, and a second electrode connected to the first drain node NDa.

The first emission control transistor T4a may include a gate electrode configured to receive a first emission control signal EM1, a first electrode connected to the first drain node NDa, and a second electrode connected to the first anode node NAa.

The first initialization transistor T5a may include a gate electrode configured to receive an initialization gate signal GR, a first electrode configured to receive an initialization voltage VINT, and a second electrode connected to a first anode node NAa.

The first operation control transistor T6a may include a gate electrode configured to receive a second emission control signal EM2, a first electrode configured to receive a first power voltage ELVDD, and a second electrode connected to the first source node NSa. The first power voltage ELVDD may be a high power voltage.

The first-first capacitor CA1a may include the first electrode connected to the second electrode of the first data write transistor T2a, and a second electrode connected to the first gate node NGa.

The first-second capacitor CA2a may include a first electrode configured to receive the first power voltage ELVDD, and a second electrode connected to the first gate node NGa.

The first light emitting element LE1 may include a first electrode connected to the first anode node NAa, and a second electrode configured to receive a second power voltage ELVSS. The second power voltage ELVSS may be a low power voltage. The second power voltage ELVSS may be lower than the first power voltage ELVDD. For example, the first electrode of the first light emitting element LE1 may be the pixel electrode PE of FIG. 2, and the second electrode of the first light emitting element LE1 may be the common electrode CE of FIG. 2.

According to some embodiments, each of the first driving transistor T1a, the first data write transistor T2a, the first compensation transistor T3a, the first emission control transistor T4a, the first initialization transistor T5a, and the first operation control transistor T6a may be a PMOS transistor. According to some embodiments, at least one of the first driving transistor T1a, the first data write transistor T2a, the first compensation transistor T3a, the first emission control transistor T4a, the first initialization transistor T5a, or the first operation control transistor T6a may be an NMOS transistor. In addition, although FIG. 4 illustrates that the first pixel circuit PC1 includes six transistors and two capacitors, this is an example and embodiments are not limited thereto.

The second pixel circuit PC2 connected to the second light emitting element LE2 may include a second driving transistor T1b, a second data write transistor T2b, a second compensation transistor T3b, a second emission control transistor T4b, a second initialization transistor T5b, the first operation control transistor T6a, a second-first capacitor CA1b, and a second-second capacitor CA2a. A first electrode of the second data write transistor T2b may be configured to receive a second data voltage VDATA2.

The first pixel circuit PC1 and the second pixel circuit PC2 may share the first operation control transistor T6a.

The second driving transistor T1b may include a gate electrode connected to a second gate node NGb, a first electrode connected to the first source node NSa, and a second electrode connected to a second drain node NDb.

According to some embodiments, the second driving transistor T1b may be a dual transistor including a second-first driving transistor T1-1b and a second-second driving transistor T1-2b. The second-first driving transistor T1-1b may include a gate electrode connected to the second gate node NGb, a first electrode connected to the first source node NSa, and a second electrode connected to a first electrode of the second-second driving transistor T1-2b. The second-second driving transistor T1-2b may include a gate electrode connected to the second gate node NGb, the first electrode connected to the second electrode of the second-first driving transistor T1-1b, and a second electrode connected to the second drain node NDb.

The first operation control transistor T6a may be electrically connected to the first driving transistor T1a and the second driving transistor T1b through the first source node NSa. For example, the first operation control transistor Toa may be electrically connected to the first-first driving transistor T1-1a and the second-first driving transistor T1-1b through the first source node NSa.

Referring to FIG. 5, according to some embodiments, the third pixel circuit PC3 connected to the third light emitting element LE3 may include a third driving transistor T1c, a third data write transistor T2c, a third compensation transistor T3c, a third emission control transistor T4c, a third initialization transistor T5c, a second operation control transistor T6c, a third-first capacitor CA1c, and a third-second capacitor CA2c.

The fourth pixel circuit PC4 connected to the fourth light emitting element LE4 may include a fourth driving transistor T1d, a fourth data write transistor T2d, a fourth compensation transistor T3d, a fourth emission control transistor T4d, a fourth initialization transistor T5d, the second operation control transistor T6c, a fourth-first capacitor CA1d, and a fourth-second capacitor CA2d.

The third pixel circuit PC3 and the fourth pixel circuit PC4 may share the second operation control transistor T6c.

The third driving transistor T1c may include a gate electrode connected to a third gate node NGc, a first electrode connected to a second source node NSc, and a second electrode connected to a third drain node NDc.

According to some embodiments, the third driving transistor T1c may be a dual transistor including a third-first driving transistor T1-1c and a third-second driving transistor T1-2c. The third-first driving transistor T1-1c may include a gate electrode connected to the third gate node NGc, a first electrode connected to the second source node NSc, and a second electrode connected to a first electrode of the third-second driving transistor T1-2c. The third-second driving transistor T1-2c may include a gate electrode connected to the third gate node NGc, the first electrode connected to the second electrode of the third-first driving transistor T1-1c, and a second electrode connected to the third drain node NDc.

The fourth driving transistor T1d may include a gate electrode connected to a fourth gate node NGd, a first electrode connected to the second source node NSc, and a second electrode connected to a fourth drain node NDd.

According to some embodiments, the fourth driving transistor T1d may be a dual transistor including a fourth-first driving transistor T1-1d and a fourth-second driving transistor T1-2d. The fourth-first driving transistor T1-1d may include a gate electrode connected to the fourth gate node NGd, a first electrode connected to the second source node NSc, and a second electrode connected to a first electrode of the fourth-second driving transistor T1-2d. The fourth-second driving transistor T1-2d may include a gate electrode connected to the fourth gate node NGd, the first electrode connected to the second electrode of the fourth-first driving transistor T1-1d, and a second electrode connected to the fourth drain node NDd.

The second operation control transistor T6c may be electrically connected to the third driving transistor T1c and the fourth driving transistor T1d through the second source node NSc. For example, the second operation control transistor T6c may be electrically connected to the third-first driving transistor T1-1c and the fourth-first driving transistor T1-1d through the second source node NSc.

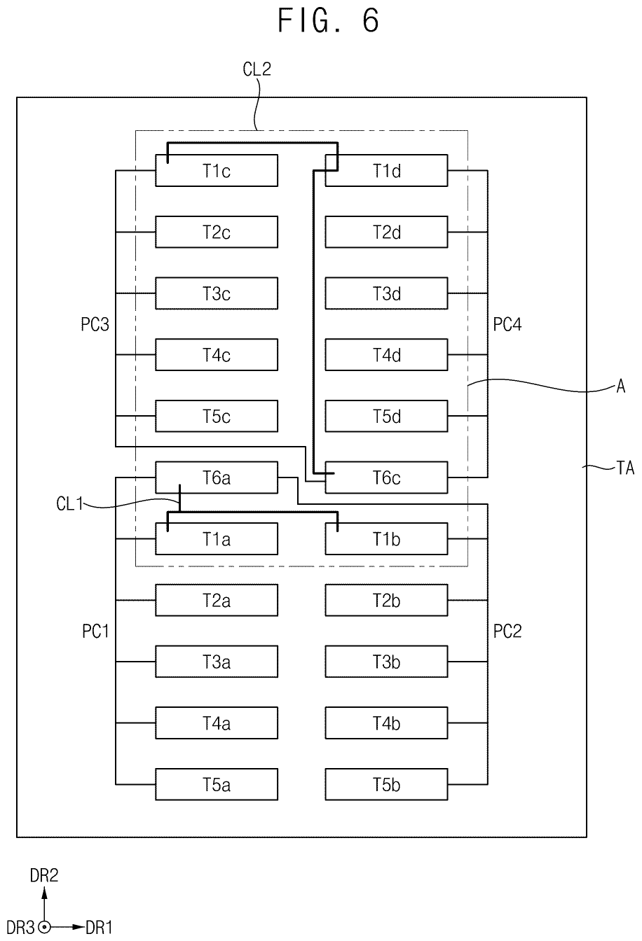

FIG. 6 is a plan view schematically illustrating an example of the first to fourth pixel circuits included in the thin film transistor array of FIG. 3.

Referring to FIG. 6, according to some embodiments, the first driving transistor T1a, the first data write transistor T2a, the first compensation transistor T3a, the first emission control transistor T4a, and the first initialization transistor T5a of the first pixel circuit PC1 may be located in a line along the second direction DR2. For example, the first driving transistor T1a, the first data write transistor T2a, the first compensation transistor T3a, the first emission control transistor T4a, and the first initialization transistor T5a may be sequentially arranged along a direction opposite to the second direction DR2.

The second pixel circuit PC2 may be located in the first direction DR1 from the first pixel circuit PC1. The second driving transistor T1b, the second data write transistor T2b, the second compensation transistor T3b, the second emission control transistor T4b, and the second initialization transistor T5b of the second pixel circuit PC2 may be arranged in a line along the second direction DR2. For example, the second driving transistor T1b, the second data write transistor T2b, the second compensation transistor T3b, the second emission control transistor T4b, and the second initialization transistor T5b may be sequentially arranged along the direction opposite to the second direction DR2.

The second driving transistor T1b may be located in the first direction DR1 from the first driving transistor Ta. The second data write transistor T2b may be located in the first direction DR1 from the first data write transistor T2a. The second compensation transistor T3b may be located in the first direction DR1 from the first compensation transistor T3a. The second emission control transistor T4b may be located in the first direction DR1 from the first emission control transistor T4a. The second initialization transistor T5b may be located in the first direction DR1 from the first initialization transistor T5a.

The third pixel circuit PC3 may be located in the second direction DR2 from the first pixel circuit PC1. The fourth pixel circuit PC4 may be located in the second direction DR2 from the second pixel circuit PC2.

The third driving transistor T1c, the third data write transistor T2c, the third compensation transistor T3c, the third emission control transistor T4c, and the third initialization transistor T5c of the third pixel circuit PC3 may be arranged in a line along the second direction DR2. For example, the third driving transistor T1c, the third data write transistor T2c, the third compensation transistor T3c, the third emission control transistor T4c, and the third initialization transistor T5c may be sequentially arranged along the direction opposite to the second direction DR2.

The fourth driving transistor T1d, the fourth data write transistor T2d, the fourth compensation transistor T3d, the fourth emission control transistor T4d, and the fourth initialization transistor T5d of the fourth pixel circuit PC4 may be arranged in a line along the second direction DR2. For example, the fourth driving transistor T1d, the fourth data write transistor T2d, the fourth compensation transistor T3d, the fourth emission control transistor T4d, and the fourth initialization transistor T5a may be sequentially arranged along the direction opposite to the second direction DR2.

The fourth driving transistor T1d may be located in the first direction DR1 from the third driving transistor T1c. The fourth data write transistor T2d may be located in the first direction DR1 from the third data write transistor T2c. The fourth compensation transistor T3d may be located in the first direction DR1 from the third compensation transistor T3c. The fourth emission control transistor T4d may be located in the first direction DR1 from the third emission control transistor T4c. The fourth initialization transistor T5d may be located in the first direction DR1 from the third initialization transistor T5c.

According to some embodiments, the first operation control transistor T6a may be located in the second direction DR2 from the first driving transistor T1a. For example, the first operation control transistor T6a may be located between the first driving transistor T1a and the third initialization transistor T5c.

The second operation control transistor T6c may be located in the second direction DR2 from the second driving transistor T1b. For example, the second operation control transistor T6c may be located between the second driving transistor T1b and the fourth initialization transistor T5d. The second operation control transistor T6c may be located in the first direction DR1 from the first operation control transistor T6a.

According to some embodiments, the first driving transistor T1a may be located between the first operation control transistor T6a and the first data write transistor T2a. The third data write transistor T2c may be located between the first operation control transistor Ta and the third driving transistor T1c.

According to some embodiments, the second driving transistor T1b may be located between the second operation control transistor T6c and the second data write transistor T2b. The fourth data write transistor T2d may be located between the second operation control transistor T6c and the fourth driving transistor T1d.

The first operation control transistor T6a may be connected to the first driving transistor T1a and the second driving transistor T1b through a first connection line CL1. The second operation control transistor T6c may be connected to the third driving transistor T1c and the fourth driving transistor T1d through a second connection line CL2.

According to embodiments, the thin film transistors included in each of the pixel circuits may be arranged in a line along the second direction DR2. Accordingly, impurities may be relatively easily doped into the substrate SUB during manufacturing process of the thin film transistor array TA. In addition, two of the pixel circuits adjacent to each other in the first direction DR1 may share one operation control transistor. Accordingly, a degree of integration of the pixel circuits PC in the thin film transistor array TA may be relatively improved. Accordingly, a resolution and a display quality of the display device DD may be relatively improved.

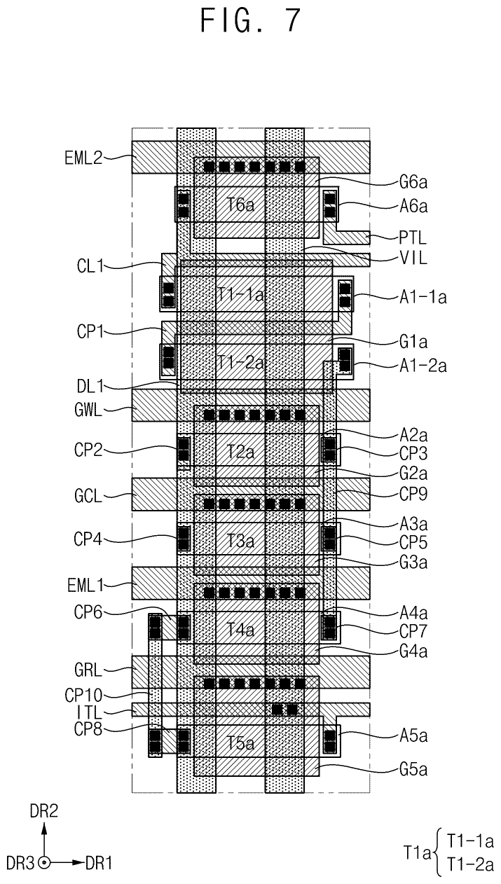

FIGS. 7 to 11 are layout views illustrating the first pixel circuit of FIG. 6.

Referring to FIGS. 6 to 11, according to some embodiments, the thin film transistor array TA may include the substrate SUB and a first conductive layer CTL1, a second conductive layer CTL2, and a third conductive layer CTL3 sequentially arranged on the substrate SUB.

FIG. 7 illustrates a stacked state of the substrate SUB, the first conductive layer CTL1, the second conductive layer CTL2, and the third conductive layer CTL3. FIGS. 8 to 11 illustrates the substrate SUB, the first conductive layer CTL1, the second conductive layer CTL2, and the third conductive layer CTL3, respectively.

Hereinafter, an example of an arrangement structure of the transistors and the wires included in the first pixel circuit PC1 of the thin film transistor array TA will be described in more detail with reference to FIGS. 6 to 11.

Referring to FIGS. 6 to 8, the substrate SUB may define active portions A1-1a, A1-2a, A2a, A3a, A4a, A5a, and A6a of the first-first driving transistor T1-1a, the first-second driving transistor T1-2a, the first data write transistor T2a, the first compensation transistor T3a, the first emission control transistor T4a, the first initialization transistor T5a, and the first operation control transistor T6a. According to some embodiments, the active portions A1-1a, A1-2a, A2a, A3a, A4a, A5a, and A6a may each extend in the first direction DR1 and may be arranged in a line along the second direction DR2.

Each of the active portions A1-1a, A1-2a, A2a, A3a, A4a, A5a, and A6a may include a source region, a drain region spaced apart from the source region, and a channel region between the source region and the drain region. The channel region may be a region doped with impurities of a first conductivity type. Each of the source region and the drain region may be a region doped with impurities of a second conductivity type. For example, the first conductivity type may be n-type, and the second conductivity type may be p-type. According to some embodiments, a device isolation layer including an insulating material may be located between the active portions A1-1a, A1-2a, A2a, A3a, A4a, A5a, and A6a.

According to some embodiments, a drain region D1-1a of the active portion A1-1a of the first-first driving transistor T1-1a (hereinafter, referred to as a first-first driving drain region) may be spaced apart from a source region S1-1a of the active portion A1-1a of the first-first driving transistor T1-1a (hereinafter, referred to as a first-first driving source region) in the first direction DR1. The first-first driving source region S1-1a may be the first electrode of the first-first driving transistor T1-1a, and the first-first driving drain region D1-1a may be the second electrode of the first-first driving transistor T1-1a.

According to some embodiments, a drain region D1-2a (hereinafter, referred to as a first-second driving drain region) of the active portion A1-2a of the first-second driving transistor T1-2a may be spaced apart from a source region S1-2a (hereinafter, referred to as a first-second driving source region) of the active portion A1-2a of the first-second driving transistor T1-2a in the first direction DR1. The first-second driving source region S1-2a may be the first electrode of the first-second driving transistor T1-2a, and the first-second driving drain region D1-2a may be the second electrode of the first-second driving transistor T1-2a.

According to some embodiments, a drain region D2a (hereinafter, referred to as a first data write drain region) of the active portion A2a of the first data write transistor T2a may be spaced apart from a source region S2a (hereinafter, referred to as a first data write source region) of the active portion A2a of the first data write transistor T2a in the first direction DR1. The first data write source region S2a may be the first electrode of the first data write transistor T2a, and the first data write drain region D2a may be the second electrode of the first data write transistor T2a.

According to some embodiments, a drain region D3a (hereinafter, referred to as a first compensation drain region) of the active portion A3a of the first compensation transistor T3a may be spaced apart from a source region S3a (hereinafter, referred to as a first compensation source region) of the active portion A3a of the first compensation transistor T3a in the first direction DR1. The first compensation source region S3a may be the first electrode of the first compensation transistor T3a, and the first compensation drain region D3a may be the second electrode of the first compensation transistor T3a.

According to some embodiments, a drain region D4a (hereinafter, referred to as a first emission control drain region) of the active portion A4a of the first emission control transistor T4a may be spaced apart from a source region S4a (hereinafter, referred to as a first emission control source region) of the active portion A4a of the first emission control transistor T4a in a direction opposite to the first direction DR1. The first emission control source region S4a may be the first electrode of the first emission control transistor T4a, and the first emission control drain region D4a may be the second electrode of the first emission control transistor T4a.

According to some embodiments, a drain region D5a (hereinafter, referred to as a first initialization drain region) of the active portion A5a of the first initialization transistor T5a may be spaced apart from a source region S5a (hereinafter, referred to as a first initialization source region) of the active portion A5a of the first initialization transistor T5a in the direction opposite to the first direction DR1. The first initialization source region S5a may be the first electrode of the first initialization transistor T5a, and the first initialization drain region D5a may be the second electrode of the first initialization transistor T5a.

According to some embodiments, a drain region D6a (hereinafter, referred to as a first operation control drain region) of the active portion A6a of the first operation control transistor T6a may be spaced apart from a source region S6a (hereinafter, referred to as a first operation control source region) of the active portion A6a of the first operation control transistor T6a in the direction opposite to the first direction DR1. The first operation control source region S6a may be the first electrode of the first operation control transistor T6a, and the first operation control drain region D6a may be the second electrode of the first operation control transistor T6a.

A first insulating layer may be located on the substrate SUB. The first insulating layer may include an inorganic insulating material and/or an organic insulating material.

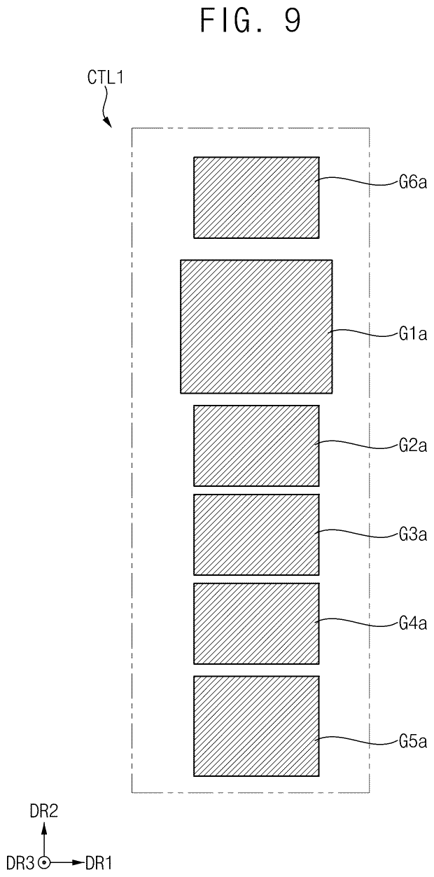

Referring further to FIG. 9, the first conductive layer CTL1 may be located on the substrate SUB. The first conductive layer CTL1 may be located on the first insulating layer. The first conductive layer CTL1 may include a conductive material.

The first conductive layer CTL1 may include first to sixth gate electrodes G1a, G2a, G3a, G4a, G5a, and G6a spaced apart from each other. According to some embodiments, the first insulating layer may have a structure including insulating patterns corresponding to the first to sixth gate electrodes G1a, G2a, G3a, G4a, G5a, and G6a, respectively.

The first gate electrode G1a may overlap a channel region C1-1a of the active portion A1-1a of the first-first driving transistor T1-1a and a channel region C1-2a of the active portion A1-2a of the first-second driving transistor T1-2a in a plan view. The first gate electrode Ga may be the gate electrode of the first-first driving transistor T1-1a and the gate electrode of the first-second driving transistor T1-2a.

According to some embodiments, the second gate electrode G2a may be spaced apart from the first gate electrode G1a in the direction opposite to the second direction DR2. The second gate electrode G2a may overlap a channel region C2a of the active portion A2a of the first data write transistor T2a in a plan view. The second gate electrode G2a may be the gate electrode of the first data write transistor T2a.

According to some embodiments, the third gate electrode G3a may be spaced apart from the second gate electrode G2a in the direction opposite to the second direction DR2. The third gate electrode G3a may overlap a channel region C3a of the active portion A3a of the first compensation transistor T3a in a plan view. The third gate electrode G3a may be the gate electrode of the first compensation transistor T3a.

According to some embodiments, the fourth gate electrode G4a may be spaced apart from the third gate electrode G3a in the direction opposite to the second direction DR2. The fourth gate electrode G4a may overlap a channel region C4a of the active portion A4a of the first emission control transistor T4a in a plan view. The fourth gate electrode G4a may be the gate electrode of the first emission control transistor T4a.

According to some embodiments, the fifth gate electrode G5a may be spaced apart from the fourth gate electrode G4a in the direction opposite to the second direction DR2. The fifth gate electrode G5a may overlap a channel region C5a of the active portion A5a of the first initialization transistor T5a in a plan view. The fifth gate electrode G5a may be the gate electrode of the first initialization transistor T5a.

According to some embodiments, the sixth gate electrode G6a may be spaced apart from the first gate electrode G1a in the second direction DR2. The sixth gate electrode G6a may overlap a channel region C6a of the active portion A6a of the first operation control transistor T6a in a plan view. The sixth gate electrode G6a may be the gate electrode of the first operation control transistor T6a.

A second insulating layer may be located on the first conductive layer CTL1. The second insulating layer may include an inorganic insulating material and/or an organic insulating material.

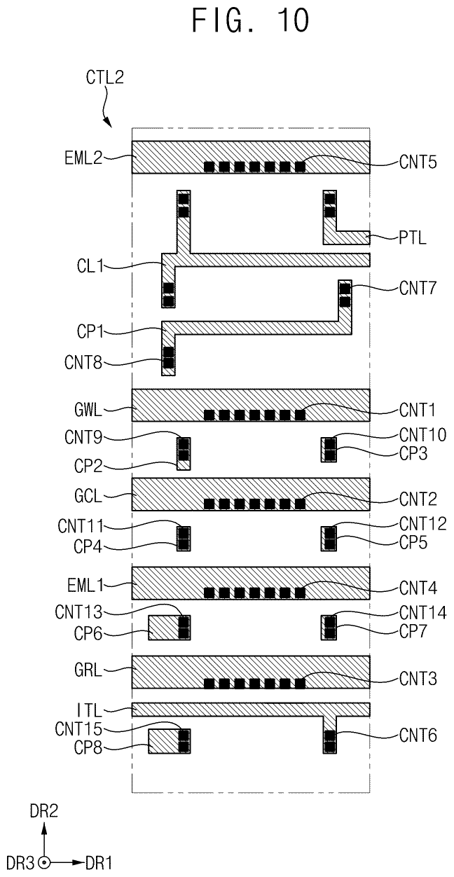

Referring further to FIG. 10, the second conductive layer CTL2 may be located on the first conductive layer CTL1. The second conductive layer CTL2 may be located on the second insulating layer. The second conductive layer CTL2 may include a conductive material.

The second conductive layer CTL2 may include gate lines, emission control lines, a first initialization voltage transfer line ITL, a power transfer line PTL, the first connection line CL1, and first to eighth connection patterns CP1, CP2, CP3, CP4, CP5, CP6, CP7, and CP8 spaced apart from each other. The gate lines may include a first data write gate line GWL, a first compensation gate line GCL, and a first initialization gate line GRL. The emission control lines may include a first-first emission control line EML1 and a second emission control line EML2.

The first data write gate line GWL, the first compensation gate line GCL, the first initialization gate line GRL, the first-first emission control line EML1, and the second emission control line EML2 may each extend in the first direction DR1 and may be spaced apart from each other in the second direction DR2.

The data write gate signal GW of FIG. 4 may be provided to the first data write gate line GWL. A portion of the first data write gate line GWL may overlap a portion of the second gate electrode G2a in a plan view. The portion of the first data write gate line GWL may be connected to the portion of the second gate electrode G2a through a first contact hole CNT1 penetrating an insulating layer below (e.g., the second insulating layer).

The compensation gate signal GC of FIG. 4 may be provided to the first compensation gate line GCL. A portion of the first compensation gate line GCL may overlap a portion of the third gate electrode G3a in a plan view. The portion of the first compensation gate line GCL may be connected to the portion of the third gate electrode G3a through a second contact hole CNT2 penetrating an insulating layer below (e.g., the second insulating layer).

The initialization gate signal GR of FIG. 4 may be provided to the first initialization gate line GRL. A portion of the first initialization gate line GRL may overlap a portion of the fifth gate electrode G5a in a plan view. The portion of the first initialization gate line GRL may be connected to the portion of the fifth gate electrode G5a through a third contact hole CNT3 penetrating an insulating layer below (e.g., the second insulating layer).

The first emission control signal EM1 of FIG. 4 may be provided to the first-first emission control line EML1. A portion of the first-first emission control line EML1 may overlap a portion of the fourth gate electrode G4a in a plan view. The portion of the first-first emission control line EML1 may be connected to the portion of the fourth gate electrode G4a through a fourth contact hole CNT4 penetrating an insulating layer below (e.g., the second insulating layer).

The second emission control signal EM2 of FIG. 4 may be provided to the second emission control line EML2. A portion of the second emission control line EML2 may overlap a portion of the sixth gate electrode G6a in a plan view. The portion of the second emission control line EML2 may be connected to the portion of the sixth gate electrode G6a through a fifth contact hole CNT5 penetrating an insulating layer below (e.g., the second insulating layer).

A portion of the first initialization voltage transfer line ITL may overlap the first initialization source region S5a in a plan view. The portion of the first initialization voltage transfer line ITL may be connected to the first initialization source region S5a through a sixth contact hole CNT6 penetrating an insulating layer below (e.g., the first and second insulating layers).

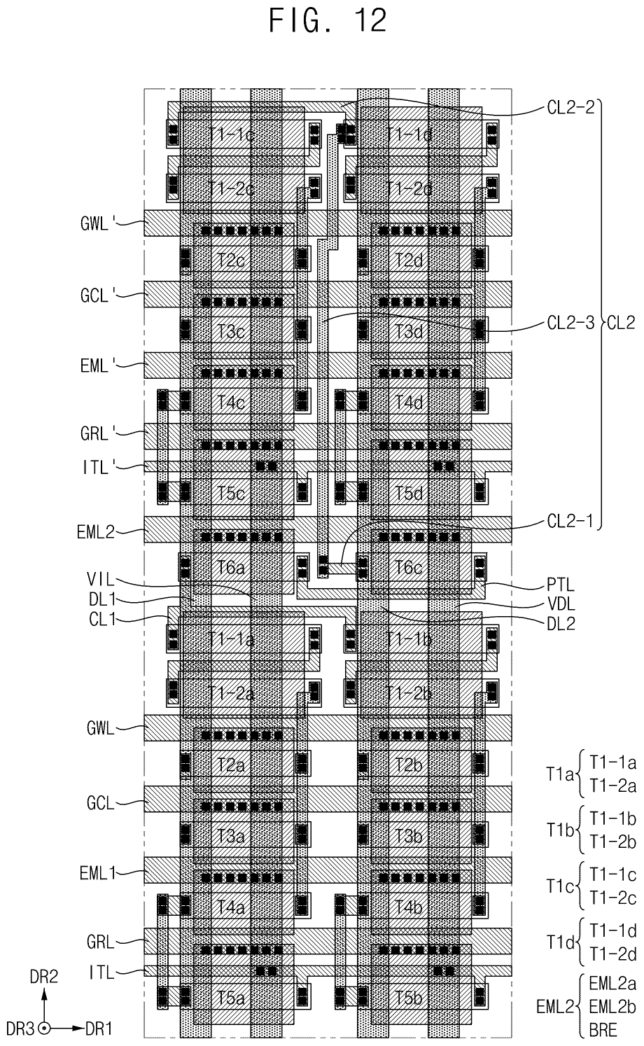

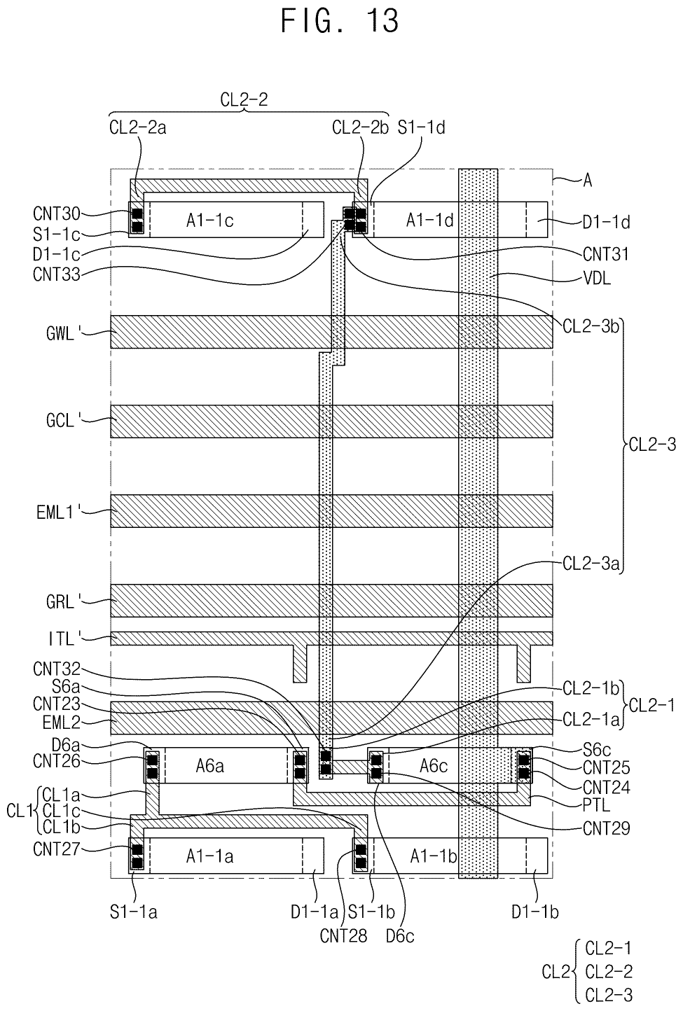

The power transfer line PTL may transfer the first power voltage ELVDD of FIG. 4 to the first operation control source region S6a. The first connection line CL1 may electrically connect the first operation control transistor T6a, the first-first driving transistor T1-1a, and the second-first driving transistor T1-1b. The power transfer line PTL and the first connection line CL1 will be described in detail later with reference to FIGS. 12 and 13 together with the second connection line CL2.

A first end portion of the first connection pattern CP1 may overlap the first-first driving drain region D1-1a in a plan view. The first end portion of the first connection pattern CP1 may be connected to the first-first driving drain region D1-1a through a seventh contact hole CNT7 penetrating an insulating layer below (e.g., the first and second insulating layers).

A second end portion of the first connection pattern CP1 may overlap the first-second driving source region S1-2a in a plan view. The second end portion of the first connection pattern CP1 may be connected to the first-second driving source region S1-2a through an eighth contact hole CNT8 penetrating an insulating layer below (e.g., the first and second insulating layers). Accordingly, the first-first driving drain region D1-1a may be electrically connected to the first-second driving source region S1-2a through the first connection pattern CP1.

The second connection pattern CP2 may overlap the first data write source region S2a in a plan view. The second connection pattern CP2 may be connected to the first data write source region S2a through a ninth contact hole CNT9 penetrating an insulating layer below (e.g., the first and second insulating layers).

The third connection pattern CP3 may overlap the first data write drain region D2a in a plan view. The third connection pattern CP3 may be connected to the first data write drain region D2a through a tenth contact hole CNT10 penetrating an insulating layer below (e.g., the first and second insulating layers). According to some embodiments, the third connection pattern CP3 may be electrically connected to the first electrode of the first-first capacitor CA1a of FIG. 4. According to some embodiments, the first electrode of the first-first capacitor CA1a may be located on the third conductive layer CTL3.

The fourth connection pattern CP4 may overlap the first compensation source region S3a in a plan view. The fourth connection pattern CP4 may be connected to the first compensation source region S3a through an eleventh contact hole CNT11 penetrating an insulating layer below (e.g., the first and second insulating layers). According to some embodiments, the fourth connection pattern CP4 may be electrically connected to the second electrode of the first-first capacitor CA1a, the second electrode of the first-second capacitor CA2a of FIG. 4, and the first gate electrode G1a. According to some embodiments, the second electrode of the first-first capacitor CA1a and the second electrode of the first-second capacitor CA2a may be located on the third conductive layer CTL3.

The fifth connection pattern CP5 may overlap the first compensation drain region D3a in a plan view. The fifth connection pattern CP5 may be connected to the first compensation drain region D3a through a twelfth contact hole CNT12 penetrating an insulating layer below (e.g., the first and second insulating layers).

The sixth connection pattern CP6 may overlap the first emission control source region S4a in a plan view. The sixth connection pattern CP6 may be connected to the first emission control source region S4a through a thirteenth contact hole CNT13 penetrating an insulating layer below (e.g., the first and second insulating layers).

The seventh connection pattern CP7 may overlap the first emission control drain region D4a in a plan view. The seventh connection pattern CP7 may be connected to the first emission control drain region D4a through a fourteenth contact hole CNT14 penetrating an insulating layer below (e.g., the first and second insulating layers).

The eighth connection pattern CP8 may overlap the first initialization source region S5a in a plan view. The eighth connection pattern CP8 may be connected to the first initialization source region S6a through a fifteenth contact hole CNT15 penetrating an insulating layer below (e.g., the first and second insulating layers).

A third insulating layer may be located on the second conductive layer CTL2. The third insulating layer may include an inorganic insulating material and/or an organic insulating material.

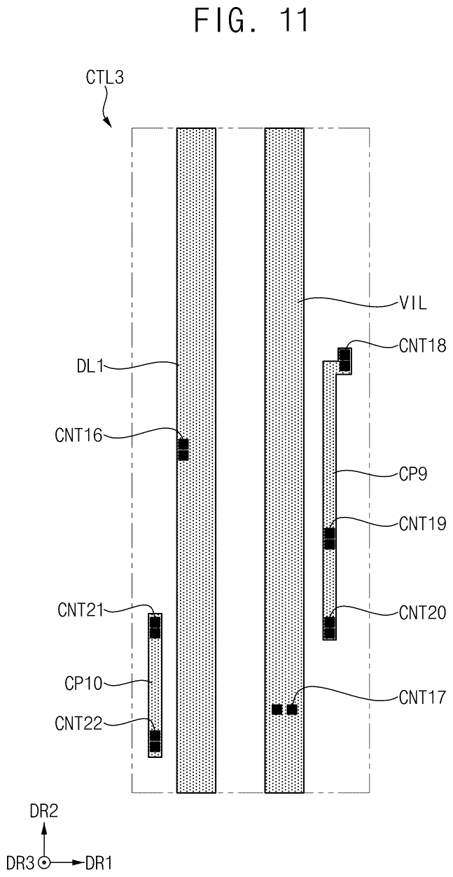

Referring further to FIG. 11, the third conductive layer CTL3 may be located on the second conductive layer CTL2. The third conductive layer CTL3 may be located on the third insulating layer. The third conductive layer CTL3 may include a conductive material.

The third conductive layer CTL3 may include a first data line DL1, an initialization voltage line VIL, a ninth connection pattern CP9, and a tenth connection pattern CP10 spaced apart from each other.

The first data line DL1 may extend in the second direction DR2. The first data voltage VDATA1 of FIG. 4 may be provided to the first data line DL1. A portion of the first data line DL1 may overlap the second connection pattern CP2 in a plan view. The portion of the first data line DL1 may be connected to the second connection pattern CP2 through a sixteenth contact hole CNT16 penetrating an insulating layer below (e.g., the third insulating layer). Accordingly, the first data voltage VDATA1 may be provided to the first data write source region S2a through the first data line DL1 and the second connection pattern CP2.

The initialization voltage line VIL may extend in the second direction DR2 and may be spaced apart from the first data line DL1 in the first direction DR1. The initialization voltage VINT of FIG. 4 may be provided to the initialization voltage line VIL. A portion of the initialization voltage line VIL may overlap a portion of the first initialization voltage transfer line ITL in a plan view. The portion of the initialization voltage line VIL may be connected to the portion of the first initialization voltage transfer line ITL through a seventeenth contact hole CNT17 penetrating an insulating layer below (e.g., the third insulating layer). Accordingly, the initialization voltage VINT may be provided to the first initialization source region S5a through the initialization voltage line VIL and the first initialization voltage transfer line ITL.

A first portion of the ninth connection pattern CP9 may overlap the first-second driving drain region D1-2a in a plan view. The first portion of the ninth connection pattern CP9 may be connected to the first-second driving drain region D1-2a through an eighteenth contact hole CNT18 penetrating an insulating layer below (e.g., the first to third insulating layers).

A second portion of the ninth connection pattern CP9 may overlap the fifth connection pattern CP5 in a plan view. The second portion of the ninth connection pattern CP9 may be connected to the fifth connection pattern CP5 through a nineteenth contact hole CNT19 penetrating an insulating layer below (e.g., the third insulating layer). Accordingly, the first-second driving drain region D1-2a may be electrically connected to the first compensation drain region D3a through the ninth connection pattern CP9 and the fifth connection pattern CP5.

A third portion of the ninth connection pattern CP9 may overlap the seventh connection pattern CP7 in a plan view. The third portion of the ninth connection pattern CP9 may be connected to the seventh connection pattern CP7 through a twentieth contact hole CNT20 penetrating an insulating layer below (e.g., the third insulating layer). Accordingly, the first-second driving drain region D1-2a may be electrically connected to the first emission control source region S4a through the ninth connection pattern CP9 and the seventh connection pattern CP7.

A first end portion of the tenth connection pattern CP10 may overlap the sixth connection pattern CP6 in a plan view. The first end portion of the tenth connection pattern CP10 may be connected to the sixth connection pattern CP6 through a twenty-first contact hole CNT21 penetrating an insulating layer below (e.g., the third insulating layer).

A second end portion of the tenth connection pattern CP10 may overlap the eighth connection pattern CP8 in a plan view. The second end portion of the tenth connection pattern CP10 may be connected to the eighth connection pattern CP8 through a twenty-second contact hole CNT22 penetrating an insulating layer below (e.g., the third insulating layer). Accordingly, the first emission control drain region D4a may be electrically connected to the first initialization drain region D5a through the sixth connection pattern CP6, the tenth connection pattern CP10, and the eighth connection pattern CP8.

As described above, an example of the arrangement structure of the first pixel circuit PC1 has been described with reference to FIGS. 7 to 11, but this is an example and embodiments are not limited thereto, and the arrangement structure of the first pixel circuit PC1 may be variously modified. In addition, an arrangement structure of each of the second to fourth pixel circuits PC2, PC3, and PC4 may be the same (or substantially the same) as or similar to the arrangement structure of the first pixel circuit PC1 described above.

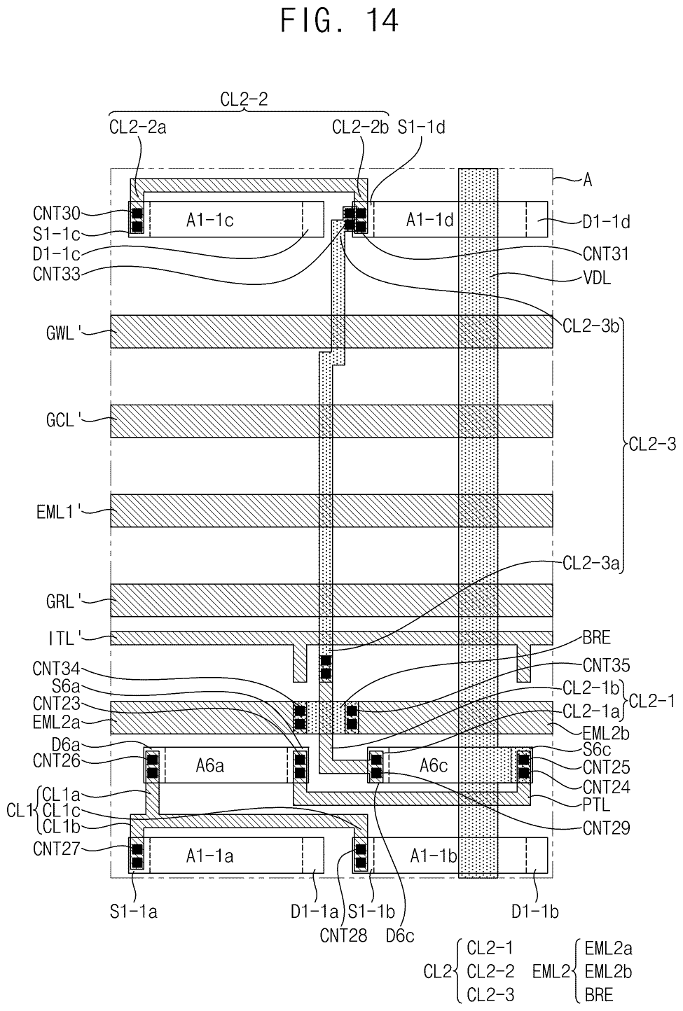

FIG. 12 is a layout view illustrating the first to fourth pixel circuits of FIG. 6. FIGS. 13 and 14 are enlarged views illustrating an area A of FIG. 6.

FIG. 12 illustrates a stacked state of the substrate SUB, the first conductive layer CTL1, the second conductive layer CTL2, and the third conductive layer CTL3. FIGS. 13 and 14 selectively illustrate some components of FIG. 12 for convenience of description.

Hereinafter, an example of an arrangement structure of the first to fourth pixel circuits PC1, PC2, PC3, and PC4 of the thin film transistor array TA adjacent to each other will be described with reference to FIGS. 12 to 14. The description of the first pixel circuit PC1 described above with reference to FIGS. 7 to 11 may be equally (or substantially equally) or similarly applied to each of the second to fourth pixel circuits PC2, PC3, and PC4. Therefore, some repeated descriptions may be omitted or simplified.

Referring to FIGS. 12 and 13, the substrate SUB may further define active portions of transistors included in the second to fourth pixel circuits PC2, PC3, and PC4.

The first conductive layer CTL1 may further include gate electrodes of each of the transistors included in the second to fourth pixel circuits PC2, PC3, and PC4.

The second conductive layer CTL2 may further include a second data write gate line GWL′, a second compensation gate line GCL′, a second initialization gate line GRL′, a first-second emission control line EML1′, a second initialization voltage transfer line ITL′, a second-first connection line CL2-1, a second-second connection line CL2-2, and connection patterns.

The third conductive layer CTL3 may further include a second data line DL2, a power voltage line VDL, a second-third connection line CL2-3, and connection patterns.

The first data write gate line GWL may extend in the first direction DR1. The first data write gate line GWL may be electrically connected to the gate electrode of the first data write transistor T2a and the gate electrode of the second data write transistor T2b.

The second data write gate line GWL′ may extend in the first direction DR1 and may be spaced apart from the first data write gate line GWL in the second direction DR2. The second data write gate line GWL′ may be electrically connected to the gate electrode of the third data write transistor T2c and the gate electrode of the fourth data write transistor T2d.

The first compensation gate line GCL may extend in the first direction DR1. The first compensation gate line GCL may be electrically connected to the gate electrode of the first compensation transistor T3a and the gate electrode of the second compensation transistor T3b.

The second compensation gate line GCL′ may extend in the first direction DR1 and may be spaced apart from the first compensation gate line GCL in the second direction DR2. The second compensation gate line GCL′ may be electrically connected to the gate electrode of the third compensation transistor T3c and the gate electrode of the fourth compensation transistor T3d.

The first initialization gate line GRL may extend in the first direction DR1. The first initialization gate line GRL may be electrically connected to the gate electrode of the first initialization transistor T5a and the gate electrode of the second initialization transistor T5b.

The second initialization gate line GRL′ may extend in the first direction DR1 and may be spaced apart from the first initialization gate line GRL in the second direction DR2. The second initialization gate line GRL′ may be electrically connected to the gate electrode of the third initialization transistor T5c and the gate electrode of the fourth initialization transistor T5d.

The first-first emission control line EML1 may extend in the first direction DR1. The first-first emission control line EML1 may be electrically connected to the gate electrode of the first emission control transistor T4a and the gate electrode of the second emission control transistor T4b.

The first-second emission control line EML1′ may extend in the first direction DR1 and may be spaced apart from the first-first emission control line EML1 in the second direction DR2. The first-second emission control line EML1′ may be electrically connected to the gate electrode of the third emission control transistor T4c and the gate electrode of the fourth emission control transistor T4d.

The second emission control line EML2 may extend in the first direction DR1. The second emission control line EML2 may be electrically connected to the gate electrode of the first operation control transistor T6a and the gate electrode of the second operation control transistor T6c.

The first initialization voltage transfer line ITL may be electrically connected to the source region of the active portion of the first initialization transistor T5a and a source region of the active portion of the second initialization transistor T5b.

The second initialization voltage transfer line ITL′ may extend in the first direction DR1 and may be spaced apart from the first initialization voltage transfer line ITL in the second direction DR2. The second initialization voltage transfer line ITL′ may be electrically connected to a source region of the active portion of the third initialization transistor T5c and a source region of the active portion of the fourth initialization transistor T5d.

The first data line DL1 may extend in the second direction DR2. The first data line DL1 may be electrically connected to the source region of the active portion of the first data write transistor T2a and a source region of the active portion of the third data write transistor T2c.

The second data line DL2 may extend in the second direction DR2 and may be spaced apart from the first data line DL1 in the first direction DR1. The second data line DL2 may be electrically connected to a source region of the active portion of the second data write transistor T2b and a source region of the active portion of the fourth data write transistor T2d.

A first end portion of the power transfer line PTL may overlap the first operation control source region S6a in a plan view. The first end portion of the power transfer line PTL may be connected to the first operation control source region S6a through a twenty-third contact hole CNT23 penetrating an insulating layer below (e.g., the first and second insulating layers).

A second end portion of the power transfer line PTL may overlap a source region S6c (hereinafter, referred to as a second operation control source region) of the active portion A6c of the second operation control transistor T6c in a plan view. The second end portion of the power transfer line PTL may be connected to the second operation control source region S6c through a twenty-fourth contact hole CNT24 penetrating an insulating layer below (e.g., the first and second insulating layers).

The power voltage line VDL may extend in the second direction DR2. The first power voltage ELVDD of FIG. 4 may be provided to the power voltage line VDL. A portion of the power voltage line VDL may overlap the second end portion of the power transfer line PTL in a plan view. The portion of the power voltage line VDL may be connected to the second end portion of the power transfer line PTL through a twenty-fifth contact hole CNT25 penetrating an insulating layer below (e.g., the third insulating layer). Accordingly, the first power voltage ELVDD may be provided to the first operation control source region S6a and the second operation control source region S6c through the power voltage line VDL and the power transfer line PTL.

The first connection line CL1 may electrically connect the first operation control transistor T6a, the first-first driving transistor T1-1a, and the second-first driving transistor T1-1b to each other. According to some embodiments, the first connection line CL1 may be located on the same (or substantially the same layer) as the gate lines GWL, GWL′, GCL, GCL′, GRL, and GRL′ and the emission control lines EML1, EML1′, and EML2.

A first end portion CL1a of the first connection line CL1 may overlap the first operation control drain region D6a in a plan view. The first end portion CL1a of the first connection line CL1 may be connected to the first operation control drain region D6a through a twenty-sixth contact hole CNT26 penetrating an insulating layer below (e.g., the first and second insulating layers).

A second end portion CL1b of the first connection line CL1 may overlap the first-first driving source region S1-1a in a plan view. The second end portion CL1b of the first connection line CL1 may be connected to the first-first driving source region S1-1a through a twenty-seventh contact hole CNT27 penetrating an insulating layer below (e.g., the first and second insulating layers). Accordingly, the first operation control drain region D6a may be electrically connected to the first-first driving source region S1-1a through the first connection line CL1.

A third end portion CL1c of the first connection line CL1 may overlap a source region S1-1b (hereinafter, referred to as a second-first driving source region) of the active portion A1-1b of the second-first driving transistor T1-1b in a plan view. The third end portion CL1c of the first connection line CL1 may be connected to the second-first driving source region S1-1b through a twenty-eighth contact hole CNT28 penetrating an insulating layer below (e.g., the first and second insulating layers). Accordingly, the first operation control drain region D6a may be electrically connected to the second-first driving source region S1-1b through the first connection line CL1.

The second connection line CL2 may electrically connect the second operation control transistor T6c, the third-first driving transistor T1-1c, and the fourth-first driving transistor T1-1d to each other.

According to some embodiments, the second connection line CL2 may include a second-first connection line CL2-1, a second-second connection line CL2-2, and a second-third connection line CL2-3. The second-third connection line CL2-3 may be located on a different layer from the second-first connection line CL2-1 and the second-second connection line CL2-2.

According to some embodiments, the second-first connection line CL2-1 and the second-second connection line CL2-2 may be located on the same (or substantially the same) layer as the gate lines GWL, GWL′, GCL, GCL′, GRL, and GRL′ and the emission control lines EML1, EML1′, and EML2. According to some embodiments, the second-third connection line CL2-3 may be located on the same (or substantially the same) layer as the data lines DL1 and DL2 and the power voltage line VDL.

A first end portion CL2-1a of the second-first connection line CL2-1 may overlap a drain region D6c (hereinafter, referred to as a second operation control drain region) of the active portion A6c of the second operation control transistor T6c in a plan view. The first end portion CL2-1a of the second-first connection line CL2-1 may be connected to the second operation control drain region D6c through a twenty-ninth contact hole CNT29 penetrating an insulating layer below (e.g., the first and second insulating layers).

The second-second connection line CL2-2 may be spaced apart from the second-first connection line CL2-1 in the second direction DR2.

A first end portion CL2-2a of the second-second connection line CL2-2 may overlap a source region S1-1c (hereinafter, referred to as a third-first driving source region) of the active portion A1-1c of the third-first driving transistor T1-1c in a plan view. The first end portion CL2-2a of the second-second connection line CL2-2 may be connected to the third-first driving source region S1-1c through a thirtieth contact hole CNT30 penetrating an insulating layer below (e.g., the first and second insulating layers).

A second end portion CL2-2b of the second-second connection line CL2-2 may overlap a source region S1-1d (hereinafter, referred to as a fourth-first driving source region) of the active portion A1-1d of the fourth-first driving transistor T1-1d in a plan view. The second end portion CL2-2b of the second-second connection line CL2-2 may be connected to the fourth-first driving source region S1-1d through a thirty-first contact hole CNT31 penetrating an insulating layer below (e.g., the first and second insulating layers).

The second-third connection line CL2-3 may connect a second end portion CL2-1b of the second-first connection line CL2-1 and the second end portion CL2-2b of the second-second connection line CL2-2 to each other. The second-third connection line CL2-3 may extend in the second direction DR2.

A first end portion CL2-3a of the second-third connection line CL2-3 may overlap the second end portion CL2-1b of the second-first connection line CL2-1 in a plan view. The first end portion CL2-3a of the second-third connection line CL2-3 may be connected to the second end portion CL2-1b of the second-first connection line CL2-1 through a thirty-second contact hole CNT32 penetrating an insulating layer below (e.g., the third insulating layer).

A second end portion CL2-3b of the second-third connection line CL2-3 may overlap the second end portion CL2-2b of the second-second connection line CL2-2 in a plan view. The second end portion CL2-3b of the second-third connection line CL2-3 may be connected to the second end portion CL2-2b of the second-second connection line CL2-2 through a thirty-third contact hole CNT33 penetrating an insulating layer below (e.g., the third insulating layer).

Accordingly, the second operation control drain region D6c may be electrically connected to the third-first driving source region S1-1c and the fourth-first driving source region S1-1d through the second-first connection line CL2-1, the second-third connection line CL2-3, and the second-second connection line CL2-2.

As described above, the first connection line CL1 may contact each of the first operation control drain region D6a, the first-first driving source region S1-1a, and the second-first driving source region S1-1b through the contact hole through the contact hole. The second-first connection line CL2-1 may contact the second operation control drain region D6c through the contact hole. The second-second connection line CL2-2 may contact each of the third-first driving source region S1-1c and the fourth-first driving source region S1-1d through the contact hole. According to some embodiments, the first connection line CL1, the second-first connection line CL2-1, and the second-second connection line CL2-2 may be located on the same (or substantially the same) layer as each other. Accordingly, a deviation in characteristics between the driving transistors T1-1a, T1-1b, T1-1c, and T1-1d may be prevented or reduced.

In a plan view, the second-third connection line CL2-3 extending in the second direction DR2 may cross at least one of the gate lines GWL, GWL′, GCL, GCL′, GRL, or GRL′, the emission control lines EML1, EML1′, or EML2, or the initialization voltage transfer lines ITL and ITL′ extending in the first direction DR1. The second-third connection line CL2-3 may be located on a different layer from the crossing line.

According to some embodiments, as illustrated in FIG. 13, the second-third connection line CL2-3 may cross the second emission control line EML2, the second initialization voltage transfer line ITL′, the second initialization gate line GRL′, the first-second emission control line EML1′, the second compensation gate line GCL′, and the second data write gate line GWL′ in a plan view. In a plan view, the second-first connection line CL2-1 may not cross the gate lines GWL, GWL′, GCL, GCL′, GRL, and GRL′, the emission control lines EML1, EML1′, and EML2, and the initialization voltage transfer lines ITL and ITL′ extending in the first direction DR1.

According to some embodiments, as illustrated in FIG. 14, the second-third connection line CL2-3 may cross the second initialization voltage transfer line ITL′, the second initialization gate line GRL′, the first-second emission control line EML1′, the second compensation gate line GCL′, and the second data write gate line GWL′ in a plan view. In a plan view, the second-first connection line CL2-1 may cross the second emission control line EML2 extending in the first direction DR1.

In the embodiments of FIG. 14, the second emission control line EML2 may include a first extension portion EML2a, a second extension portion EML2b, and a bridge electrode BRE. The first extension portion EML2a and the second extension portion EML2b may each extend in the first direction DR1.

The first extension portion EML2a may overlap the gate electrode of the first operation control transistor T6a in a plan view, and may be electrically connected to the gate electrode of the first operation control transistor T6a through a contact hole.

The second extension portion EML2b may be spaced apart from the first extension portion EML2a in the first direction DR1 with the bridge electrode BRE therebetween. The second extension portion EML2b may overlap the gate electrode of the second operation control transistor T6c in a plan view, and may be electrically connected to the gate electrode of the second operation control transistor T6c through a contact hole.

The bridge electrode BRE may be located on a different layer from the first extension portion EML2a, the second extension portion EML2b, and the second-first connection line CL2-1. According to some embodiments, the bridge electrode BRE may be located on the same (or substantially the same) layer as the data lines DL1 and DL2, the power voltage line VDL, and the second-third connection line CL2-3. The bridge electrode BRE may cross the second-first connection line CL2-1 in a plan view.

The bridge electrode BRE may electrically connect the first extension portion EML2a and the second extension portion EML2b to each other. A first end portion of the bridge electrode BRE may be connected to the first extension portion EML2a through a thirty-fourth contact hole CNT34 penetrating an insulating layer below (e.g., the third insulating layer). A second end portion of the bridge electrode BRE may be connected to the second extension portion EML2b through a thirty-fifth contact hole CNT35 penetrating an insulating layer below (e.g., the third insulating layer).

FIG. 14 illustrates that the second-first connection line CL2-1 crosses one of the gate lines GWL, GWL′, GCL, GCL′, GRL, and GRL′, the emission control lines EML1, EML1′, and EML2, and the initialization voltage transfer lines ITL and ITL′ extending in the first direction DR1 in a plan view, but embodiments are not limited thereto, and the second-first connection line CL2-1 may cross two or more lines extending in the first direction DR1 in a plan view. In this case, each of the lines crossing the second-first connection line CL2-1 may have a structure similar to the second emission control line EML2 of FIG. 14.

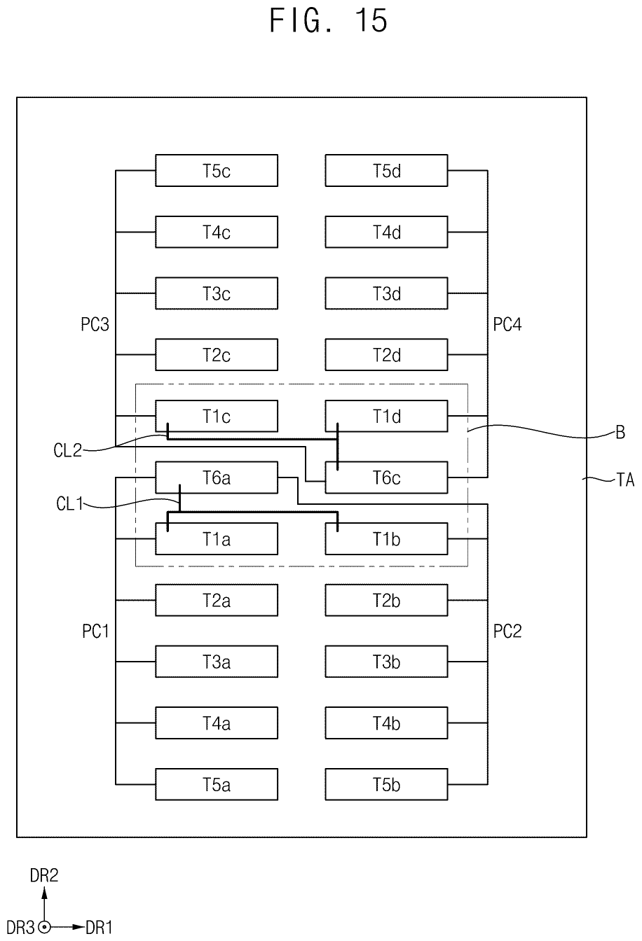

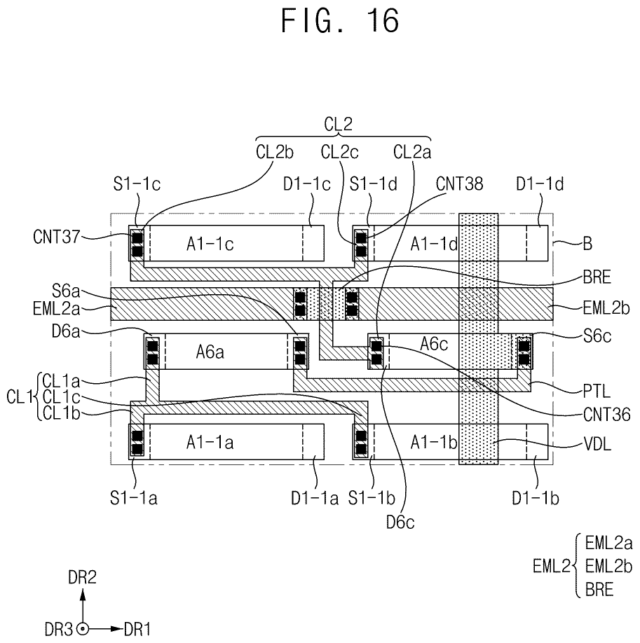

FIG. 15 is a plan view schematically illustrating an example of the first to fourth pixel circuits included in the thin film transistor array of FIG. 3. FIG. 16 is an enlarged view illustrating an area B of FIG. 15.

Hereinafter, embodiments of FIGS. 15 to 17 will be described focusing on differences from the embodiments described above with reference to FIGS. 6 to 13, and some repeated descriptions that overlaps the description described above with reference to FIGS. 6 to 13 may be omitted or simplified. FIG. 15 may correspond to FIG. 6, and FIG. 16 may correspond to FIG. 14.

Referring to FIG. 15, the transistors T1c, T2c, T3c, T4c, and T5c of the third pixel circuit PC3 may be located symmetrically (e.g., a mirrored form or arrangement) to the transistors T1a, T2a, T3a, T4a, and T5a of the first pixel circuit PC1 with respect to the first operation control transistor T6a. The transistors T1d, T2d, T3d, T4d, and T5d of the fourth pixel circuit PC4 may be arranged symmetrically (e.g., a mirrored form or arrangement) to the transistors T1b, T2b, T3b, T4b, and T5b of the second pixel circuit PC2 with respect to the second operation control transistor T6c.

According to some embodiments, the first driving transistor T1a may be adjacent to the first operation control transistor T6a in the direction opposite to the second direction DR2. No other transistor may be located between the first driving transistor T1a and the first operation control transistor T6a. For example, the first driving transistor T1a, the first data write transistor T2a, the first compensation transistor T3a, the first emission control transistor T4a, and the first initialization transistor T5a may be sequentially arranged along the direction opposite to the second direction DR2.

According to some embodiments, the third driving transistor T1c may be adjacent to the first operation control transistor T6a in the second direction DR2. No other transistor may be located between the third driving transistor T1c and the first operation control transistor T6a. For example, the third driving transistor T1c, the third data write transistor T2c, the third compensation transistor T3c, the third emission control transistor T4c, and the third initialization transistor T5a may be sequentially arranged along the second direction DR2.

According to some embodiments, the first driving transistor T1a may be located between the first operation control transistor Toa and the first data write transistor T2a. The third driving transistor T1c may be located between the first operation control transistor T6a and the third data write transistor T2c.

According to some embodiments, the second driving transistor T1b may be adjacent to the second operation control transistor T6c in the direction opposite to the second direction DR2. No other transistor may be located between the second driving transistor T1b and the second operation control transistor T6c. For example, the second driving transistor T1b, the second data write transistor T2b, the second compensation transistor T3b, the second emission control transistor T4b, and the second initialization transistor T5a may be sequentially arranged along the direction opposite to the second direction DR2.

According to some embodiments, the fourth driving transistor T1d may be adjacent to the second operation control transistor T6c in the second direction DR2. No other transistor may be located between the fourth driving transistor T1d and the second operation control transistor T6c. For example, the fourth driving transistor T1d, the fourth data write transistor T2d, the fourth compensation transistor T3d, the fourth emission control transistor T4d, and the fourth initialization transistor T5a may be sequentially arranged along the second direction DR2.

According to some embodiments, the second driving transistor T1b may be located between the second operation control transistor T6c and the second data write transistor T2b. The fourth driving transistor T1d may be located between the second operation control transistor T6c and the fourth data write transistor T2d.

The first operation control transistor T6a may be connected to the first driving transistor T1a and the second driving transistor T1b through the first connection line CL1. The second operation control transistor T6c may be connected to the third driving transistor T1c and the fourth driving transistor T1d through the second connection line CL2.

As illustrated in FIG. 15, when the transistors T1c, T2c, T3c, T4c, and T5c of the third pixel circuit PC3 and the transistors T1a, T2a, T3a, T4a, and T5a of the first pixel circuit PC1 are arranged in a mirrored form or configuration and the transistors T1d, T2d, T3d, T4d, and T5d of the fourth pixel circuit PC4 and the transistors T1b, T2b, T3b, T4b, and T5b of the second pixel circuit PC2 are arranged in a mirrored form or configuration, the second operation control transistor T6c may be relatively more easily connected to the third driving transistor T1c and the fourth driving transistor T1d.

Referring to FIG. 16, the first connection line CL1 may electrically connect the first operation control transistor T6a, the first-first driving transistor T1-1a, and the second-first driving transistor T1-1b to each other. The first connection line CL1 may be the same (or substantially the same) as the first connection line CL1 described above with reference to FIG. 13.

The second connection line CL2 may electrically connect the second operation control transistor T6c, the third-first driving transistor T1-1c, and the fourth-first driving transistor T1-1d to each other. According to some embodiments, the second connection line CL2 may be located on the same (or substantially the same) layer as the first connection line CL1.

A first end portion CL2a of the second connection line CL2 may overlap the second operation control drain region D6c in a plan view. The first end portion CL2a of the second connection line CL2 may be connected to the second operation control drain region D6c through a thirty-sixth contact hole CNT36 penetrating an insulating layer below (e.g., the first and second insulating layers).

A second end portion CL2b of the second connection line CL2 may overlap the third-first driving source region S1-1c in a plan view. The second end portion CL2b of the second connection line CL2 may be connected to the third-first driving source region S1-1c through a thirty-seventh contact hole CNT37 penetrating an insulating layer below (e.g., the first and second insulating layers).

A third end portion CL2c of the second connection line CL2 may overlap the fourth-first driving source region S1-1d in a plan view. The third end portion CL2c of the second connection line CL2 may be connected to the fourth-first driving source region S1-1d through a thirty-eighth contact hole CNT38 penetrating an insulating layer below (e.g., the first and second insulating layers).

In a plan view, the second connection line CL2 may cross at least one of the gate lines, the emission control lines, or the initialization voltage transfer lines extending in the first direction DR1. The second connection line CL2 may be located on a different layer from the crossing line.

According to some embodiments, the second connection line CL2 may cross the second emission control line EML2 in a plan view. The second emission control line EML2 crossing the second connection line CL2 may include the first extension portion EML2a, the second extension portion EML2b, and the bridge electrode BRE.

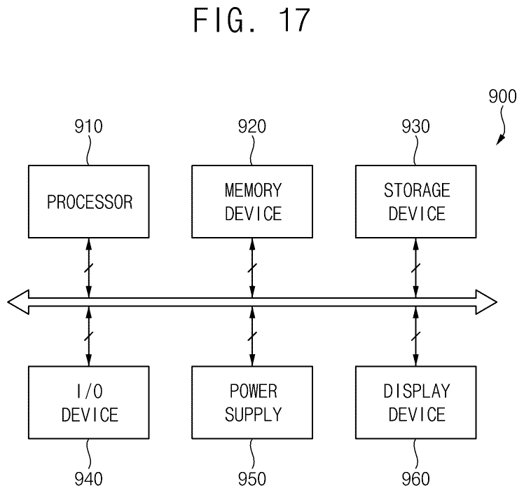

FIG. 17 is a block diagram illustrating an electronic device according to some embodiments.

Referring to FIG. 17, according to some embodiments, an electronic device may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. According to some embodiments, the electronic device 900 may be implemented as a television. According to some embodiments, the electronic device 900 may be implemented as a smart phone. However, embodiments are not limited thereto, according to some embodiments, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. According to some embodiments, the processor 910 may be a microprocessor, a central processing unit (“CPU”), an application processor (“AP”), or the like. The processor 910 may be coupled to other components via an address bus, a control bus, a data bus, or the like. According to some embodiments, the processor 910 may be coupled to an extended bus such as a peripheral component interconnection (“PCI”) bus.

The memory device 920 may store data for operations of the electronic device 900. According to some embodiments, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

According to some embodiments, the storage device 930 may include a solid state drive (“SSD”) device, a hard disk drive (“HDD”) device, a CD-ROM device, or the like. According to some embodiments, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled to other components via the buses or other communication links. According to some embodiments, the display device 960 may be included in the I/O device 940.

Although aspects of some embodiments and implementations have been described herein, other embodiments and modifications will be apparent from this description. Accordingly, the invention is not limited to such embodiments, but rather to the broader scope of the appended claims and various modifications and equivalent arrangements as would be apparent to a person of ordinary skill in the art.

What is claimed is:

1. A thin film transistor array comprising:
a first gate line extending in a first direction;
a first data line extending in a second direction crossing the first direction;
a second data line extending in the second direction, the second data line being spaced apart from the first data line in the first direction;
a first data write transistor electrically connected to the first gate line and the first data line;
a second data write transistor electrically connected to the first gate line and the second data line, the second data write transistor being arranged in the first direction from the first data write transistor;
a first driving transistor electrically connected to the first data write transistor, the first driving transistor being arranged in the second direction from the first data write transistor;
a second driving transistor electrically connected to the second data write transistor, the second driving transistor being arranged in the first direction from the first driving transistor, the second driving transistor being arranged in the second direction from the second data write transistor; and
a first operation control transistor electrically connected to the first driving transistor and the second driving transistor, the first operation control transistor being arranged in the second direction from the first driving transistor.

2. The thin film transistor array of claim 1, wherein the first data write transistor, the first driving transistor, and the first operation control transistor are arranged in a line along the second direction, and
wherein the second data write transistor and the second driving transistor are arranged in a line along the second direction.

3. The thin film transistor array of claim 1, further comprising:
a first compensation transistor electrically connected to the first data write transistor and the first driving transistor, the first compensation transistor being arranged in a direction opposite to the second direction from the first data write transistor;
a first emission control transistor electrically connected to the first driving transistor and the first compensation transistor, the first emission control transistor being arranged in the direction opposite to the second direction from the first compensation transistor; and
a first initialization transistor electrically connected to the first emission control transistor, the first initialization transistor being arranged in the direction opposite to the second direction from the first emission control transistor, and
wherein the first initialization transistor, the first emission control transistor, the first compensation transistor, the first data write transistor, the first driving transistor, and the first operation control transistor are arranged in a line along the second direction.

4. The thin film transistor array of claim 3, further comprising:
a second compensation transistor electrically connected to the second data write transistor and the second driving transistor, the second compensation transistor being arranged in the direction opposite to the second direction from the second data write transistor;
a second emission control transistor electrically connected to the second driving transistor and the second compensation transistor, the second emission control transistor being arranged in the direction opposite to the second direction from the second compensation transistor; and
a second initialization transistor electrically connected to the second emission control transistor, the second initialization transistor being arranged in the direction opposite to the second direction from the second emission control transistor, and
wherein the second initialization transistor, the second emission control transistor, the second compensation transistor, the second data write transistor, and the second driving transistor are arranged in a line along the second direction.

5. The thin film transistor array of claim 4, wherein the second compensation transistor is arranged in the first direction from the first compensation transistor,
wherein the second emission control transistor is arranged in the first direction from the first emission control transistor, and
wherein the second initialization transistor is arranged in the first direction from the first initialization transistor.

6. The thin film transistor array of claim 1, further comprising:
a first connection line electrically connecting a drain region of the first operation control transistor, a source region of the first driving transistor, and a source region of the second driving transistor to each other.

7. The thin film transistor array of claim 6, wherein the first connection line is on a same layer as the first gate line.

8. The thin film transistor array of claim 1, further comprising:
a second gate line extending in the first direction, the second gate line being spaced apart from the first gate line in the second direction;
a third data write transistor electrically connected to the second gate line and the first data line, the third data write transistor being arranged in the second direction from the first operation control transistor;
a fourth data write transistor electrically connected to the second gate line and the second data line, the fourth data write transistor being arranged in the first direction from the third data write transistor;
a third driving transistor electrically connected to the third data write transistor, the third driving transistor being arranged in the second direction from the first operation control transistor;
a fourth driving transistor electrically connected to the fourth data write transistor, the fourth driving transistor being arranged in the first direction from the third driving transistor; and
a second operation control transistor electrically connected to the third driving transistor and the fourth driving transistor, the second operation control transistor being arranged in the first direction from the first operation control transistor.

9. The thin film transistor array of claim 8, wherein the second operation control transistor is between the second driving transistor and the fourth driving transistor.

10. The thin film transistor array of claim 8, wherein the first data write transistor, the first driving transistor, the first operation control transistor, the third data write transistor, and the third driving transistor are arranged in a line along the second direction, and
wherein the second data write transistor, the second driving transistor, the second operation control transistor, the fourth data write transistor, and the fourth driving transistor are arranged in a line along the second direction.

11. The thin film transistor array of claim 8, wherein the third data write transistor is between the first operation control transistor and the third driving transistor, and
wherein the fourth data write transistor is between the second operation control transistor and the fourth driving transistor.

12. The thin film transistor array of claim 8, wherein the third driving transistor is between the first operation control transistor and the third data write transistor, and
wherein the fourth driving transistor is between the second operation control transistor and the fourth data write transistor.

13. The thin film transistor array of claim 8, further comprising:
a second connection line electrically connecting a drain region of the second operation control transistor, a source region of the third driving transistor, and a source region of the fourth driving transistor to each other.

14. The thin film transistor array of claim 13, wherein the second connection line is on a same layer as the first gate line and the second gate line.

15. The thin film transistor array of claim 13, further comprising:
an emission control line extending in the first direction, the emission control line being configured to provide an emission control signal to a gate electrode of the first operation control transistor and a gate electrode of the second operation control transistor, and
wherein the second connection line crosses the emission control line in a plan view.

16. The thin film transistor array of claim 15, wherein the emission control line includes:
a first extension portion overlapping the gate electrode of the first operation control transistor in the plan view;
a second extension portion on a same layer as the first extension portion, the second extension portion being spaced apart from the first extension portion in the first direction, the second extension portion overlapping the gate electrode of the second operation control transistor in the plan view; and
a bridge electrode on a different layer from the first extension portion and the second extension portion, the bridge electrode electrically connecting the first extension portion and the second extension portion to each other, and
wherein the second connection line crosses the bridge electrode in the plan view.

17. A thin film transistor array comprising:
a first gate line extending in a first direction;
a second gate line extending in the first direction, the second gate line being spaced apart from the first gate line in a second direction crossing the first direction;
a first data line extending in the second direction;
a second data line extending in the second direction, the second data line being spaced apart from the first data line in the first direction;
a first driving transistor electrically connected to the first gate line and the first data line;
a second driving transistor electrically connected to the first gate line and the second data line, the second driving transistor being arranged in the first direction from the first driving transistor;
a third driving transistor electrically connected to the second gate line and the first data line, the third driving transistor being arranged in the second direction from the first driving transistor;
a fourth driving transistor electrically connected to the second gate line and the second data line, the fourth driving transistor being arranged in the first direction from the third driving transistor, the fourth driving transistor being arranged in the second direction from the second driving transistor;
a first operation control transistor electrically connected to the first driving transistor and the second driving transistor, the first operation control transistor being between the first driving transistor and the third driving transistor; and
a second operation control transistor electrically connected to the third driving transistor and the fourth driving transistor, the second operation control transistor being between the second driving transistor and the fourth driving transistor.

18. The thin film transistor array of claim 17, further comprising:
a first connection line electrically connecting a drain region of the first operation control transistor, a source region of the first driving transistor, and a source region of the second driving transistor to each other; and
a second connection line electrically connecting a drain region of the second operation control transistor, a source region of the third driving transistor, and a source region of the fourth driving transistor to each other.

19. A display device comprising:
first to fourth light emitting elements adjacent to each other;
a first driving transistor electrically connected to the first light emitting element;
a second driving transistor electrically connected to the second light emitting element, the second driving transistor being arranged in a first direction from the first driving transistor;
a third driving transistor electrically connected to the third light emitting element, the third driving transistor being arranged in a second direction crossing the first direction from the first driving transistor;
a fourth driving transistor electrically connected to fourth light emitting element, the fourth driving transistor being arranged in the first direction from the third driving transistor, the fourth driving transistor being arranged in the second direction from the second driving transistor;
a first operation control transistor electrically connected to the first driving transistor and the second driving transistor, the first operation control transistor being arranged between the first driving transistor and the third driving transistor; and
a second operation control transistor electrically connected to the third driving transistor and the fourth driving transistor, the second operation control transistor being arranged between the second driving transistor and the fourth driving transistor.

20. The display device of claim 19, further comprising:
a first connection line electrically connecting a drain region of the first operation control transistor, a source region of the first driving transistor, and a source region of the second driving transistor to each other; and
a second connection line electrically connecting a drain region of the second operation control transistor, a source region of the third driving transistor, and a source region of the fourth driving transistor to each other.

21. An electronic device comprising:
a display device; and
a power supply configured to provide power to the display device,
wherein the display device comprises:
first to fourth light emitting elements adjacent to each other;
a first driving transistor electrically connected to the first light emitting element;
a second driving transistor electrically connected to the second light emitting element, the second driving transistor being arranged in a first direction from the first driving transistor;
a third driving transistor electrically connected to the third light emitting element, the third driving transistor being arranged in a second direction crossing the first direction from the first driving transistor;
a fourth driving transistor electrically connected to fourth light emitting element, the fourth driving transistor being arranged in the first direction from the third driving transistor, the fourth driving transistor being arranged in the second direction from the second driving transistor;
a first operation control transistor electrically connected to the first driving transistor and the second driving transistor, the first operation control transistor being arranged between the first driving transistor and the third driving transistor; and
a second operation control transistor electrically connected to the third driving transistor and the fourth driving transistor, the second operation control transistor being arranged between the second driving transistor and the fourth driving transistor.
